(19) United States
(12) Patent Application Publication
(10) Pub. No.: US 2022/0278207 A1
(43) Pub. Date: Sep. 1, 2022

(54) SEMICONDUCTOR DEVICE AND METHOD FOR PRODUCING SAME

(71) Applicant: ROHM CO., LTD., Kyoto-shi, Kyoto (JP)

(72) Inventor: Yuu ENOMOTO, Kyoto-shi, Kyoto (JP)

(21) Appl. No.: 17/638,060

(22) PCT Filed: Aug. 6, 2020
(86) PCT No.: PCT/JP2020/030208

§ 371 Date: Feb. 24, 2022

(30) Foreign Application Priority Data
Aug. 26, 2019 (JP) 2019-153947

(51) Int. Cl. H01L 29/32; H01L 29/66; H01L 29/739; H01L 29/40; H01L 29/423; H01L 21/265; H01L 21/263

(52) U.S. Cl. CPC H01L 29/32; H01L 29/66348; H01L 29/7397; H01L 29/401; H01L 29/42364; H01L 21/26506; H01L 21/2636; H01L 29/66734; H01L 29/7813

(57) ABSTRACT

A semiconductor device includes a semiconductor layer, a crystal defect region formed in the semiconductor layer, and an insulating layer formed on the semiconductor layer, composed of an insulator containing silicon, and including, in the insulator, an Si—H bond in which a dangling bond of silicon atom is hydrogen-terminated.

### TECHNICAL FIELD

The present invention relates to a semiconductor device and a manufacturing method for the same.

### BACKGROUND ART

Patent Literature discloses a semiconductor device including a semiconductor layer, a crystal defect region, and an insulating layer. The crystal defect region is formed in the semiconductor layer. The insulating layer is formed on the semiconductor layer.

### CITATION LIST

### Patent Literature

Patent Literature 1: WO 2016/051970A1

### SUMMARY OF INVENTION

### Technical Problem

One embodiment of the present invention provides a semiconductor device having a highly reliable insulating layer and a manufacturing method for the same.

### Solution to Problem

One embodiment of the present invention provides a semiconductor device including a semiconductor layer, a crystal defect region formed in the semiconductor layer, and an insulating layer formed on the semiconductor layer, composed of an insulator containing silicon, and including, in the insulator, an Si—H bond in which a dangling bond of silicon atom is hydrogen-terminated. With this structure, it is possible to provide a semiconductor device having a highly reliable insulating layer.

One embodiment of the present invention provides a manufacturing method for a semiconductor device including steps of, preparing a wafer, forming an insulating layer composed of an insulator containing silicon on the wafer, forming a crystal defect region in the wafer by at least one of an ion irradiation method and an electron beam irradiation method after forming the insulating layer, and introducing a hydrogen ion into the insulating layer to hydrogen-terminate a dangling bond of a silicon atom in the insulating layer after forming the crystal defect region.

The foregoing and still other objects, features, and effects of the present invention will be made clear from the description of the embodiments to be described below with reference to the accompanying drawings.

### BRIEF DESCRIPTION OF DRAWINGS

FIG. 1 is a plan view showing a semiconductor device according to a first embodiment of the present invention.

FIG. 2 is an enlarged view of a region II shown in FIG. 1.

FIG. 3 is a cross-sectional view taken along a line III-III shown in FIG. 2.

FIG. 4 is an enlarged view of a main part in FIG. 3.

FIG. 5A is an enlarged view showing a main part of a barrier electrode according to a first configuration example.

FIG. 5B is an enlarged view showing a main part of a barrier electrode according to a second configuration example.

FIG. 5C is an enlarged view showing a main part of a barrier electrode according to a third configuration example.

FIG. 5D is an enlarged view showing a main part of a barrier electrode according to a fourth configuration example.

FIG. 6A is a cross-sectional view for illustrating an example of amanufacturingmethod for the semiconductor device shown in FIG. 1.

FIG. 6B is a cross-sectional view showing a step following FIG. 6A.

FIG. 6C is a cross-sectional view showing a step following FIG. 6B.

FIG. 6D is a cross-sectional view showing a step following FIG. 6C.

FIG. 6E is a cross-sectional view showing a step following FIG. 6D.

FIG. 6F is a cross-sectional view showing a step following FIG. 6E.

FIG. 6G is a cross-sectional view showing a step following FIG. 6F.

FIG. 6H is a cross-sectional view showing a step following FIG. 6G.

FIG. 6I is a cross-sectional view showing a step following FIG. 6H.

FIG. 6J is a cross-sectional view showing a step following FIG. 6I.

FIG. 6K is a cross-sectional view showing a step following FIG. 6J.

FIG. 6L is a cross-sectional view showing a step following FIG. 6K.

FIG. 6M is a cross-sectional view showing a step following FIG. 6L.

FIG. 6N is a cross-sectional view showing a step following FIG. 6M.

FIG. 6O is a cross-sectional view showing a step following FIG. 6N.

FIG. 6P is a cross-sectional view showing a step following FIG. 6O.

FIG. 6Q is a cross-sectional view showing a step following FIG. 6P.

FIG. 6R is a cross-sectional view showing a step following FIG. 6Q.

FIG. 6S is a cross-sectional view showing a step following FIG. 6R.

FIG. 6T is a cross-sectional view showing a step following FIG. 6S.

FIG. 6U is a cross-sectional view showing a step following FIG. 6T.

FIG. 7 is an enlarged view corresponding to FIG. 2 and showing a semiconductor device according to a second embodiment of the present invention.

FIG. 8 is a cross-sectional view taken along a line VIII-VIII shown in FIG. 7.

FIG. 9A is a cross-sectional view for illustrating an example of a manufacturing method for the semiconductor device shown in FIG. 7.

FIG. 9B is a cross-sectional view showing a step following FIG. 9A.

FIG. 9C is a cross-sectional view showing a step following FIG. 9B.

FIG. 9D is a cross-sectional view showing a step following FIG. 9C.

FIG. 9E is a cross-sectional view showing a step following FIG. 9D.

FIG. 9F is a cross-sectional view showing a step following FIG. 9E.

FIG. 9G is a cross-sectional view showing a step following FIG. 9F.

FIG. 9H is a cross-sectional view showing a step following FIG. 9G.

FIG. 9I is a cross-sectional view showing a step following FIG. 9H.

FIG. 9J is a cross-sectional view showing a step following FIG. 9I.

FIG. 9K is a cross-sectional view showing a step following FIG. 9J.

FIG. 9L is a cross-sectional view showing a step following FIG. 9K.

FIG. 9M is a cross-sectional view showing a step following FIG. 9L.

FIG. 10 is a cross-sectional view corresponding to FIG. 3 and showing a semiconductor device according to a third embodiment of the present invention.

FIG. 11 is a cross-sectional view corresponding to FIG. 8 and showing a semiconductor device according to a fourth embodiment of the present invention.

### DESCRIPTION OF EMBODIMENTS

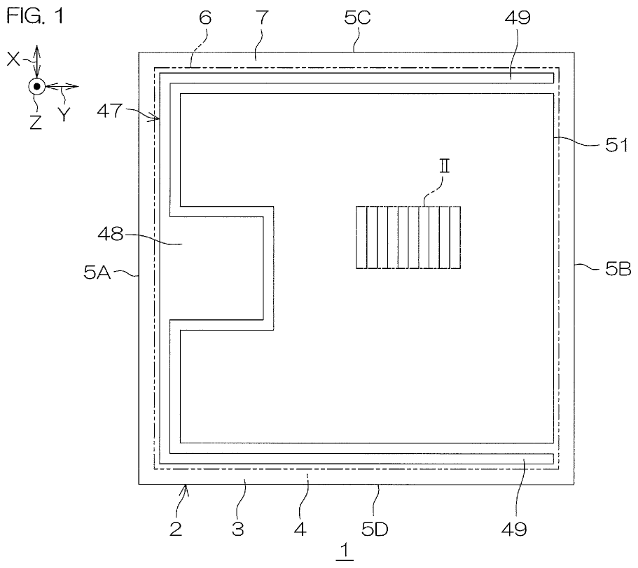

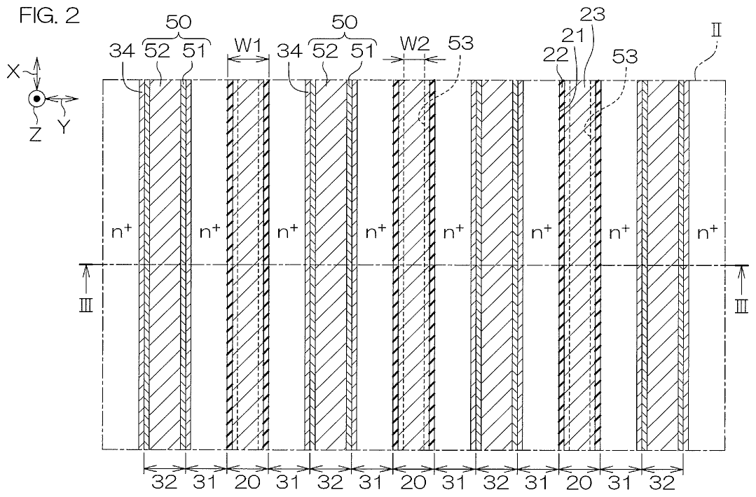

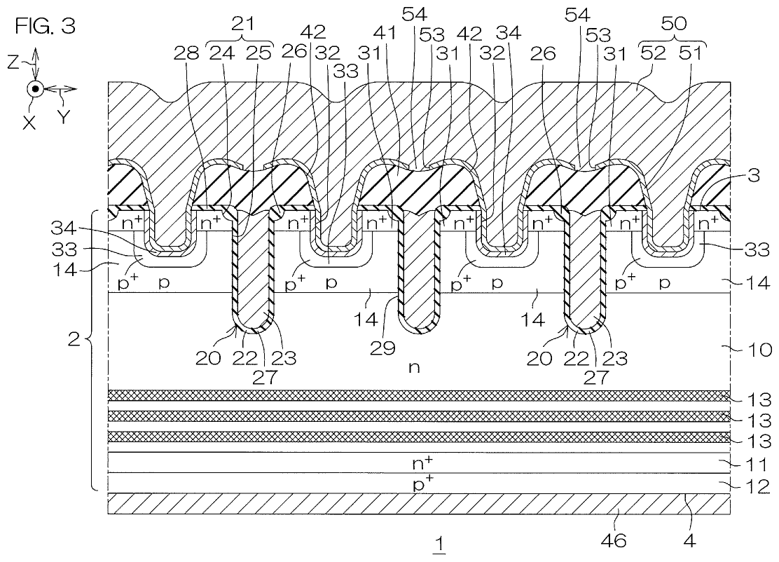

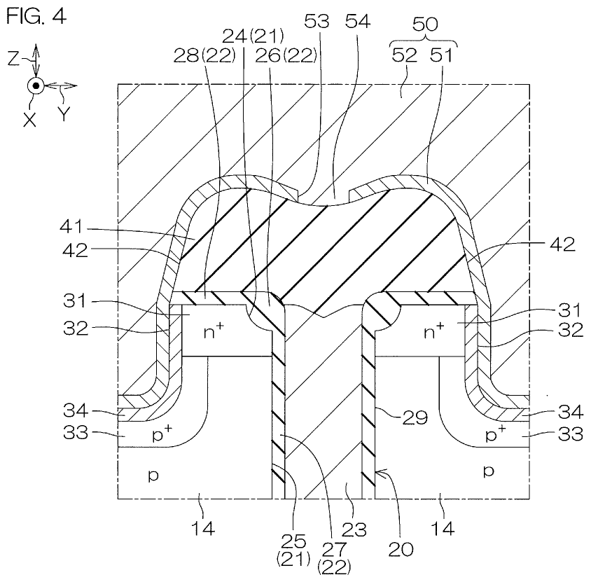

FIG. 1 is a plan view showing a semiconductor device 1 according to a first embodiment of the present invention. FIG. 2 is an enlarged view of a region II shown in FIG. 1. FIG. 3 is a cross-sectional view taken along a line III-III shown in FIG. 2. FIG. 4 is an enlarged view of a main part in FIG. 3.

Referring to FIGS. 1 to 4, the semiconductor device 1 is a semiconductor switching device including an IGBT (Insulated Gate Bipolar Transistor) . The semiconductor device 1 includes a silicon-made semiconductor layer 2 formed in a rectangular parallelepiped shape. In this embodiment, the semiconductor layer 2 has a single-layer structure composed of an FZ (Floating Zone) substrate that is formed by an FZ method or a CZ (Czochralski) substrate that is formed by a CZ method (FZ substrate in this embodiment).

The semiconductor layer 2 includes a first main surface 3 on one side, a second main surface 4 on the other side, and four side surfaces 5A, 5B, 5C, 5D connecting the first main surface 3 and the second main surface 4. The side surfaces 5A to 5D include a first side surface 5A, a second side surface 5B, a third side surface 5C, and a fourth side surface 5D.

The first main surface 3 and the second main surface 4 are each formed in a quadrilateral shape in a plan view in their normal directions Z (hereinafter referred to simply as a “plan view”) . The first side surface 5A and the second side surface 5B extend in a first direction X along the first main surface 3 and oppose each other in a second direction Y intersecting the first direction X. The third side surface 5C and the fourth side surface 5D extend in the second direction Y and oppose each other in the first direction X. Specifically, the second direction Y is orthogonal to the first direction X.

The semiconductor layer 2 includes a device region 6 and an outer region 7. The device region 6 is a region in which a major portion of the IGBT is formed. The device region 6 is formed in the semiconductor layer 2 in a manner spaced inward from the side surfaces 5A to 5D in a plan view. The device region 6 may be formed in a quadrilateral shape in a plan view.

The outer region 7 is a region outside the device region 6. The outer region 7 is formed as a band shape extending along a peripheral edge of the device region 6 in a plan view. In this embodiment, the outer region 7 is formed in an annular shape (specifically quadrilateral annular shape) surrounding the device region 6 in a plan view.

Referring to FIG. 3, the semiconductor device 1 includes an n-type (first conductivity type) drift region 10 forming a surface layer portion of the semiconductor layer 2. The drift region 10 is formed by using the FZ substrate. That is, the drift region 10 is formed in the semiconductor layer 2 over an entire region excluding the other semiconductor regions. An n-type impurity concentration of the drift region 10 may be 1.0×10¹³ cm⁻³ or more and 1.0×10¹⁵ cm⁻³ or less.

The semiconductor device 1 includes an n⁺-type buffer region 11 formed in a surface layer portion of the second main surface 4 of the semiconductor layer 2. The buffer region 11 may be referred to as field stop region. The buffer region is formed to suppress the expansion of a depletion layer during turn-off operation as one of its purposes. The buffer region 11 may be formed in an entire surface layer portion of the second main surface 4. The buffer region 11 has an n-type impurity concentration exceeding the n-type impurity concentration of the drift region 10. The n-type impurity concentration of the buffer region 11 may be 1.0×10¹⁴ cm⁻³ or more and 1.0×10¹⁸ cm⁻³ or less.

The semiconductor device 1 includes a p⁺-type (second conductivity type) collector region 12 formed in a surface layer portion of the second main surface 4 of the semiconductor layer 2. Specifically, the collector region 12 is formed in a surface layer portion of the second main surface 4 side in the buffer region 11. The collector region 12 may be formed in the entire surface layer portion of the second main surface 4. A p-type impurity concentration of the collector region 12 may be 1.0×10¹⁶ cm⁻³ or more and 1.0×10¹⁸ cm⁻³ or less.

The semiconductor device 1 includes a plurality of crystal defect regions 13 formed in the semiconductor layer 2. The crystal defect regions 13 are shown by hatching in FIG. 3. The plurality of crystal defect regions 13 are formed in regions closer to the second main surface 4 than the first main surface 3. Specifically, the plurality of crystal defect regions 13 are formed in a region between the first main surface 3 and the buffer region 11. The plurality of crystal defect regions 13 are formed in a mutually spaced manner in the normal direction Z and extend in planes or in layers in directions parallel to the first main surface 3.

In this embodiment, the plurality of (in three layers in this embodiment) crystal defect regions 13 are formed in the semiconductor layer 2 . A number of the crystal defect region 13 is arbitrary. The crystal defect region (s) 13 may be formed in the semiconductor layer 2 in only one layer or four or more layers. The crystal defect regions 13 do not necessarily have to be formed in a plurality of layers in a mutually spaced manner, but may be introduced uniformly in a predetermined thickness range of the semiconductor layer 2.

The plurality of crystal defect regions 13 each includes voids introduced into the semiconductor layer 2. That is, the crystal defect regions 13 consist of regions in which the crystal structure of the semiconductor layer 2 is reformed by the voids. The voids include point defects, holes, etc. In this embodiment, the plurality of crystal defect regions 13 are each formed as an n-type impurity regions including voids and protons.

Specifically, the plurality of crystal defect regions 13 are each formed as an n-type impurity regions including VOH defects each composed of voids (V), oxygen (O) and hydrogen (H) . The voids are introduced into the semiconductor layer 2 by at least one of an electron beam irradiation method and an ion irradiation method. The oxygen is mixed or introduced into the semiconductor layer 2 during manufacturing. The protons are introduced into the semiconductor layer 2 by an ion irradiation method. The VOH defects are formedby thermally treating the semiconductor layer 2 with the voids (V), the oxygen (O), and the hydrogen (H) introduced therein.

The VOH defects serve as donors (n-type impurity regions) that supply electrons. A density of the VOH defects of each crystal defect region 13 may be 1×10¹² cm⁻³ or more and 1×10¹⁶ cm⁻³ or less. An n-type impurity concentration of each crystal defect region 13 exceeds the n-type impurity concentration of the drift region 10.

The plurality of crystal defect regions 13 serve as at least one of a lifetime killer region, a buffer region, and a field stop region. In this embodiment, the plurality of crystal defect regions 13 are formed as a lifetime killer region. The lifetime killer region is formed to shorten the turn-off time during turn-off operation as one of its purposes.

The semiconductor device 1 includes a p-type body region 14 formed in a surface layer portion of the first main surface 3 of the semiconductor layer 2 at the device region 6. A p-type impurity concentration of the body region 14 may be 1.0×10¹⁶ cm⁻³ or more and 1.0×10¹⁸ cm⁻³ or less. The body region 14 opposes the crystal defect regions 13 with the drift region 10 interposed therebetween in the normal direction Z. In this embodiment, the body region 14 defines the device region 6.

The semiconductor device 1 includes a plurality of trench gate structures 20 formed in the first main surface 3 of the semiconductor layer 2 at the device region 6. The plurality of trench gate structures 20 are each formed in a band shape extending in the first direction X and spaced from each other in the second direction Y. The plurality of trench gate structures 20 are thereby formed in a stripe pattern extending in the first direction X in a plan view. The plurality of trench gate structures 20 oppose the crystal defect regions 13 with the drift region 10 interposed therebetween in the normal direction Z.

Specifically, each of the trench gate structures 20 includes a gate trench 21 (trench) , a gate insulating layer 22 (insulating layer), and a gate electrode 23 (electrode). The gate trench 21 is formed by entrenching the first main surface 3 toward the secondmain surface 4 . The gate trench 21 penetrates the body region 14 to reach the drift region 10. The gate trench 21 is formed in a manner spaced from the plurality of crystal defect regions 13 toward the first main surface 3.

The gate trench 21 includes a side wall and a bottom wall. The side wall of the gate trench 21 exposes the drift region 10 and the body region 14. The bottom wall of the gate trench 21 exposes the drift region 10.

Specifically, the gate trench 21 includes a first trench portion 24 and a second trench portion 25. The first trench portion 24 has a relatively large opening width and is formed closer to an opening of the gate trench 21. The first trench portion 24 is positioned in a region closer to the first main surface 3 with respect to a bottom portion of the body region 14. The second trench portion 25 has an opening width smaller than the opening width of the first trench portion 24 and extends from the first trench portion 24 through the bottom portion of the body region 14 to reach the drift region 10. The second trench portion 25 is deeper than the first trench portion 24.

The gate insulating layer 22 is formed as a film along an inner wall of the gate trench 21. The gate insulating layer 22 defines a recessed space in the gate trench 21. The gate insulating layer 22 integrally includes a first portion 26, a second portion 27 and a third portion 28.

The first portion 26 covers the first trench portion 24. The second portion 27 covers the second trench portion 25 and is integratedwith the first portion 26. The thirdportion 28 drawn out onto the first main surface 3 through an opening edge portion of the gate trench 21 and is integrated with the first portion 26. The first portion 26 is formed as a thick film portion having a thickness exceeding the thickness of the second portion 27. The first portion 26 relaxes an electric field at the opening edge portion of the gate trench 21.

The gate insulating layer 22 is composed of an insulator containing silicon. The gate insulating layer 22 preferably includes at least one of an SiO₂ layer, an SiN layer, an SiON layer, an HfSiO layer, and an HfSiON layer. The gate insulating layer 22 may have a single-layer structure composed of an SiO₂ layer, an SiN layer, an SiON layer, an HfSiO layer, or an HfSiON layer. The gate insulating layer 22 may have a laminated structure in which at least two layers of an SiO₂ layer, an SiN layer, an SiON layer, an HfSiO layer, and an HfSiON layer are laminated in any order. In this embodiment, the gate insulating layer 22 has a single-layer structure composed of an SiO₂ layer.

The gate insulating layer 22 includes an Si—H bond in which dangling bonds of silicon atoms are hydrogen-terminated by hydrogen ions in the insulator. The gate insulating layer 22 preferably has an outer surface including an Si—H bond in which dangling bonds of silicon atoms are hydrogen-terminated by hydrogen ions. The Si—H bond in the gate insulating layer is formed by introducing hydrogen ions into the gate insulating layer 22 by a hydrogen annealing treatment method.

The thickness of the gate insulating layer 22 may be 10 nm or more and 1000 nm or less. The thickness of the gate insulating layer 22 may be 10 nm or more and 50 nm or less, 50 nm or more and 100 nm, 100 nm or more and 150 nm or less, 150 nm or more and 200 nm or less, 200 nm or more and 400 nm or less, 400 nm or more and 600 nm or less, 600 nm or more and 800 nm or less, 800 nm or more and 1000 nm or less . The thickness of the gate insulating layer 22 is preferably 20 nm or more and 200 nm less.

In the structure described above, the semiconductor device 1 includes an interface region 29 covered with the gate insulating layer 22 in the semiconductor layer 2. The interface region 29 preferably has an Si—H bond in which dangling bonds of silicon atoms in the semiconductor layer 2 are hydrogen-terminated by hydrogen ions. The Si—H bond of the interface region 29 is formed by the same method as the method for the Si—H bond of the gate insulating layer 22.

The gate electrode 23 is buried in the gate trench 21 with the gate insulating layer 22 interposed therebetween. Specifically, the gate electrode 23 is buried in the recessed space defined by the gate insulating layer 22 in the gate trench 21. The gate electrode 23 has an exposed surface exposed from the gate trench 21. The exposed surface of the gate electrode 23 may be positioned closer to the bottom wall of the gate trench 21 with respect to the first main surface 3. The exposed surface of the gate electrode 23 may have a recess toward the bottom wall of the gate trench 21.

The gate electrode 23 is composed of an electrode material that allows a hydrogen ion to be passed through. The gate electrode 23 may be composed of a polysilicon imparted with conductivity by n-type impurities or p-type impurities. The gate electrode 23 is preferably composed of an n-type polysilicon.

The semiconductor device 1 includes a plurality of n+-type emitter regions 31 formed in a surface layer portion of the body region 14. An n-type impurity concentration of the emitter regions 31 exceeds the n-type impurity concentration of the drift region 10. The n-type impurity concentration of the emitter regions 31 may be 1×10¹⁹ cm⁻³ or more and 1×10²¹ cm⁻³ or less.

The plurality of emitter regions 31 are each formed in a region between mutually adjacent ones of the plurality of gate trenches 21 in a surface layer portion of the body region 14. A bottom portion of each emitter region 31 is positioned in a region closer to the first main surface 3 with respect to the bottom portion of the body region 14.

Each emitter region 31 covers the side wall of the gate trench 21 and opposes the gate electrode 23 with the gate insulating layer 22 interposed therebetween. Specifically, each emitter region 31 covers the first trench portion 24 and the second trench portion 25 of the gate trench 21 and opposes the gate electrode 23 with the first portion 26 and the second portion 27 of the gate insulating layer 22 interposed therebetween. Each emitter region 31 defines a channel region of the IGBT with the drift region 10 in the body region 14. The channel region is formed in a region along the gate insulating layer 22 in the body region 14.

The semiconductor device 1 includes contact holes 32 each formed in a lateral region to one of the gate trenches 21 in a manner spaced from the gate trench 21 in the first main surface 3 of the semiconductor layer 2. In this embodiment, the plurality of contact holes 32 are formed in either side of each gate trench 21 . Specifically, the plurality of contact holes 32 are each formed in a region between mutually adjacent ones of the plurality of gate trenches 21.

The contact holes 32 may be each formed in a band shape extending along the gate trenches 21 in a plan view. The contact holes 32 penetrate the bottom portion of each emitter region 31 to reach the body region 14. The bottom walls of the contact holes 32 are positioned in a region between the bottom portion of the body region 14 and the bottom portion of each emitter region 31.

The semiconductor device 1 includes p⁺-type contact regions 33 formed in regions along the respective contact holes 32 in a surface layer portion of the body region 14. In this embodiment, the plurality of contact regions 33 are formed along the corresponding contact holes 32, respectively. A p-type impurity concentration of the contact regions 33 exceeds the p-type impurity concentration of the body region 14. Thep-type impurity concentration of the contact regions 33 may be 1×10¹⁹ cm⁻³ or more and 1×10²¹ cm⁻³ or less.

The contact regions 33 cover bottom walls of the corresponding contact holes 32, respectively. The contact regions 33 may cover side walls of the corresponding contact holes 32, respectively. The bottom portion of each contact region 33 is positioned in a region between the bottom portion of the body region 14 and the bottom portion of each emitter region 31.

In this embodiment, the semiconductor device 1 includes a silicide layer 34 formed in a region along the wall surface of the contact hole 32 in the surface layer portion of the body region 14. In this embodiment, a plurality of silicide layers 34 are formed along a wall surface of the corresponding contact hole 32, respectively. The silicide layers 34 are formed over the entire wall surfaces of the corresponding contact holes 32, respectively.

The silicide layers 34 are electrically connected to the corresponding emitter region 31 and the corresponding contact region 33, respectively. Specifically, the silicide layers 34 each form an ohmic contact with the corresponding emitter regions 31 and the corresponding contact regions 33. The silicide layers 34 each contains an electrode material that allows hydrogen ions to be absorbed. In this embodiment, the silicide layers 34 are composed of a Ti silicide.

The semiconductor device 1 includes an intermediate insulating layer 41 covering the first main surface 3 of the semiconductor layer 2. The intermediate insulating layer 41 is referred to also as an interlayer insulating layer. The intermediate insulating layer 41 collectively covers the plurality of trench gate structures 20. That is, the intermediate insulating layer 41 collectively covers the gate trench 21, the gate insulating layer 21, and the gate electrode 23.

The intermediate insulating layer 41 is composed of an insulator that allows hydrogen ions to be passed through. The intermediate insulating layer 41 may have a single-layer structure or a laminated structure including one or both of an SiO₂ layer and an SiN layer. The intermediate insulating layer 41 may have a laminated structure including a plurality of SiO₂ layers . The interlayer insulating layer 41 may include at least one of a USG (Undoped Silicate Glass) layer, a PSG (Phosphor Silicate Glass) layer, and a BPSG (Boron Phosphor Silicate Glass) layer as an example of the SiO₂ layer.

The intermediate insulating layer 41 may include an Si—H bond in which dangling bonds of silicon atoms are hydrogen-terminated by hydrogen ions. The intermediate insulating layer 41 may have an outer surface including an Si—H bond in which dangling bonds of silicon atoms are hydrogen-terminated by hydrogen ions.

The intermediate insulating layer 41 includes a plurality of contact openings 42. The plurality of contact openings 42 include contact openings 42 which expose the gate electrodes 23. The plurality of contact openings 42 include contact openings 42 in communication with the plurality of contact holes 32, respectively. The contact openings 42 in communication with the contact holes 32 are each formed in a band shape extending along the contact holes 32 in a plan view.

The semiconductor device 1 includes a collector electrode 46 formed on the second main surface 4 of the semiconductor layer 2. The collector electrode 46 is electrically connected to the collector region 12. The collector electrode 46 forms an ohmic contact with the collector region 12.

The collector electrode 46 may include at least one of a Ti layer, an Ni layer, a Pd layer, an Au layer, an Ag layer, and an Al layer. The collector electrode 46 preferably includes a Ti layer as an ohmic electrode. The collector electrode 46 may have a single-layer structure composed of a Ti layer, an Ni layer, a Pd layer, an Au layer, an Ag layer, or an Al layer.

The collector electrode 46 may have a laminated structure in which at least two layers of a Ti layer, an Ni layer, a Pd layer, an Au layer, an Ag layer, and an Al layer are laminated in any order. The collector electrode 46 may have a laminated structure including, for example, a Ti layer, an Ni layer, a Pd layer, an Au layer, and an Ag layer laminated in this order from the second main surface 4 side.

Referring to FIG. 1, the semiconductor device 1 includes a gate main surface electrode 47 formed on the intermediate insulating layer 41. The gate main surface electrode 47 is formed over the device region 6. The gate main surface electrode 47 includes a gate pad 48 and a gate finger 49.

The gate pad 48 is formed in a region along a central portion of the first side surface 5A in a plan view. The gate pad 48 may be formed in a region along a corner portion connecting any two of the side surfaces 5A to 5D in a plan view. The gate pad 48 may be formed in a quadrilateral shape in a plan view.

The gate finger 49 is drawn out from the gate pad 48 and extends in a band shape along the peripheral edge of the device region 6. In this embodiment, the gate finger 49 extends along the first side surface 5A, the third side surface 5C, and the fourth side surface 5D to delimit the interior of the device region 6 in the three directions.

The gate finger 49 enters the corresponding plurality of contact openings 42 from above the intermediate insulating layer 41. The gate finger 49 is electrically connected to the gate electrodes 23 in the corresponding contact openings 42. A gate voltage applied to the gate pad 48 is transmitted through the gate finger 49 to the gate electrodes 23.

Referring to FIGS. 1 and 3, the semiconductor device 1 includes an emitter main surface electrode 50 formed on the intermediate insulating layer 41 in a manner spaced from the gate main surface electrode 47. The emitter main surface electrode 50 is formed over the device region 6. The emitter main surface electrode 50 covers a region defined by the gate main surface electrode 47 over the device region 6.

The emitter main surface electrode 50 enters into the contact holes 32 from on the intermediate insulating layer 41 through the corresponding contact openings 42. The emitter main surface electrode 50 is electrically connected to the body region 14, the emitter regions 31 and the contact regions 33 in the contact holes 32. An emitter voltage applied to the emitter main surface electrode 50 is transmitted through the emitter main surface electrode 50 to the body region 14, the emitter regions 31 and the contact regions 33.

Referring to FIGS. 3 and 4, specifically, the emitter main surface electrode 50 has a laminated structure including a barrier electrode 51 and a main electrode 52 laminated in this order from the intermediate insulating layer 41 side. The gate main surface electrode 47 also has a laminated structure including a barrier electrode 51 and a main electrode 52, though not shown. The structure of the emitter main surface electrode 50 will hereinafter be described, while the structure of the gate main surface electrode 47 will not be described.

The barrier electrode 51 is formed as a film along a main surface of the intermediate insulating layer 41, inner walls of the contact openings 42, and inner walls of the contact holes 32. The barrier electrode 51 defines recessed spaces in the contact openings 42 and the contact holes 32. The barrier electrode 51 is electrically connected to the silicide layers 34 in the contact holes 32.

The barrier electrode 51 contains an electrode material that allows hydrogen ions to be absorbed. The barrier electrode 51 contains hydrogen ions therein. In this embodiment, the barrier electrode 51 contains Ti (titanium) as an example of the electrode material that allows hydrogen ions to be absorbed.

The barrier electrode 51 has an opening portion 53 from which at least one of a portion of the intermediate insulating layer 41 and a portion of the semiconductor layer 2 is exposed. In this embodiment, the barrier electrode 51 has a plurality of opening portions 53. In this embodiment, each of the opening portions 53 exposes a portion of the intermediate insulating layer 41. Each of the opening portions 53 forms an introduction path for hydrogen ions.

Each opening portion 53 preferably overlaps the first main surface 3 in a plan view. It is particularly preferable that each opening portion 53 overlaps at least one of the gate trench 21, the gate insulating layer 22, and the gate electrode 23 in a plan view. It is most preferable that each opening portion 53 overlaps all of the gate trench 21, the gate insulating layer 22, and the gate electrode 23 in a plan view. That is, each opening portion 53 preferably overlaps each trench gate structure 20 in a plan view.

In this embodiment, each opening portion 53 is formed in a band shape extending along the gate trench 21 in a plan view. The plurality of opening portions 53 may be formed in a manner spaced from each other such as to overlap one of the gate trenches 21 in a plan view. Each opening portion 53 preferably has a width W2 smaller than an opening width W1 of the gate trench 21. Each opening portion 53 is preferably positioned in a region surrounded by the side wall of the gate trench 21 in a plan view.

Each opening portion 53 thereby entirely overlaps the gate trench 21 in a plan view. Each opening portion 53 may have the width W2 equal to or greater than the opening width W1 of the gate trench 21 . Each opening portion 53 may be formed in a manner surrounding the gate trench 21 in a plan view.

The main electrode 52 is formed on the barrier electrode 51. The main electrode 52 contains an electrode material that allows hydrogen ions to be passed through. The main electrode 52 may include at least one of a pure Al layer (containing Al of 99% or higher purity) , an AlSi layer, an AlCu layer, and an AlSiCu layer.

The main electrode 52 fills recessed spaces defined by the barrier electrode 51 in the contact openings 42 and the contact holes 32 to cover the barrier electrode 51. The main electrode 52 is in contact with a portion of the intermediate insulating layer 41 or a portion of the semiconductor layer 2 in each opening portion 53 of the barrier electrode 51. In this embodiment, the main electrode 52 enters into the opening portions 53 of the barrier electrode 51 and has buried portions 54 connected to the intermediate insulating layer 41. The buried portions 54 of the main electrode 52 are formed in shapes corresponding to the opening portions 53 of the barrier electrode 51.

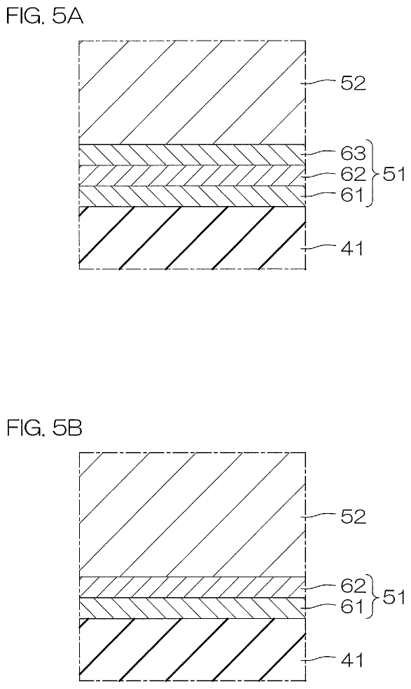

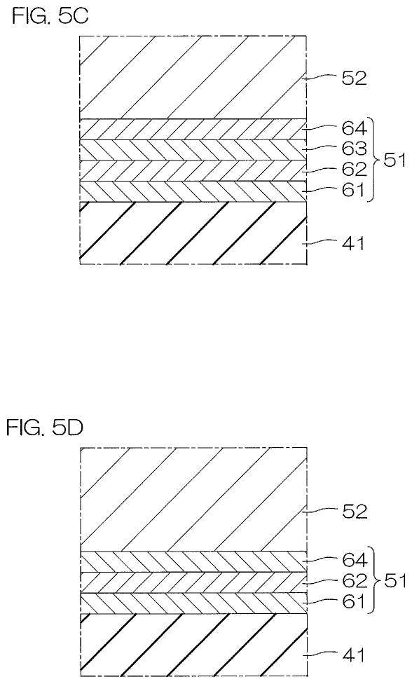

The barrier electrode 51 may take one of various forms shown in FIGs . 5A to 5D. FIGs . 5A to 5D show configuration examples of the barrier electrode 51 containing the hydrogen ion absorbing electrode material. The barrier electrode 51 may take another form other than those shown in FIGS. 5A to 5D as long as it contains the hydrogen ion absorbing electrode material.

FIG. 5A is an enlarged view showing a main part of a barrier electrode 51 according to a first configuration example. Referring to FIG. 5A, the barrier electrode 51 has a laminated structure including a Ti layer 61, a TiN layer 62, and a Ti layer 63 laminated in this order fromthe intermediate insulating layer 41 side. The Ti layer 63 may be a TiAl layer alloyed with a portion of the main electrode 52.

FIG. 5B is an enlarged view showing a main part of a barrier electrode 51 according to a second configuration example. Referring to FIG. 5B, the barrier electrode 51 has a laminated structure including a Ti layer 61 and a TiN layer 62 laminated in this order from the intermediate insulating layer 41 side.

FIG. 5C is an enlarged view showing a main part of abarrier electrode 51 according to a third configuration example. Referring to FIG. 5C, the barrier electrode 51 has a laminated structure including a Ti layer 61, a TiN layer 62, a Ti layer 63, and a W layer 64 laminated in this order from the intermediate insulating layer 41 side.

FIG. 5D is an enlarged view showing a main part of a barrier electrode 51 according to a fourth configuration example. Referring to FIG. 5D, the barrier electrode 51 has a laminated structure including a Ti layer 61, a TiN layer 62, and a W layer 64 laminated in this order from the intermediate insulating layer 41 side.

As described above, the semiconductor device 1 includes the semiconductor layer 2, the crystal defect region 13 and the gate insulating layer 22. The crystal defect region 13 is formed in the semiconductor layer 2. The gate insulating layer 22 is composed of an insulator containing silicon and includes the Si—H bond in which the dangling bond of the silicon atom is hydrogen-terminated by the hydrogen ion in the insulator.

In the gate insulating layer 22 including the dangling bonds of silicon atoms, the dangling bonds of silicon atoms serve as charge traps. Therefore, the insulating characteristics of the gate insulating layer 22 fluctuate over time. As an example, the gate threshold voltage fluctuates over time due to aging degradation of the gate insulating layer 22.

Therefore, in this embodiment, the dangling bonds of silicon atoms in the gate insulating layer 22 are hydrogen-terminated by the hydrogen ions. With this structure, the charge traps in the gate insulating layer 22 can be reduced, and thereby the aging degradation of the insulating characteristics can be suppressed. The semiconductor device 1 can therefore be provided to include such a highly reliable gate insulating layer 22.

In the structure described above, the semiconductor device 1 includes the interface region 29 covered with the gate insulating layer 22 in the semiconductor layer 2. The interface region 29 preferably has the Si—H bond in which the dangling bonds of silicon atoms in the semiconductor layer 2 are hydrogen-terminated by the hydrogen ions. With this structure, the aging degradation of the insulating characteristics can be appropriately suppressed.

The semiconductor device 1 includes the gate electrode 23, the intermediate insulating layer 41 and the barrier electrode 51. The gate electrode 23 is formed on the gate insulating layer 22. The intermediate insulating layer 41 covers the gate electrode 23. The barrier electrode 51 contains the electrode material that allows the hydrogen ions to be absorbed. That is, the barrier electrode 51 contains the hydrogen ions therein. The barrier electrode 51 covers the intermediate insulating layer 41 and has the opening portion 53 from which a portion of the intermediate insulating layer 41 or a portion of the semiconductor layer 41 is exposed. In this embodiment, a portion of the intermediate insulating layer 41 is exposed from the opening portion 53.

With the structure described above, since the hydrogen ions are introduced through the opening portion 53 of the barrier electrode 51 into the gate insulating layer 22 during formation of the Si—H bond in the gate insulating layer 22, absorption of the hydrogen ions by the barrier electrode 51 can be suppressed. It is therefore possible to appropriately form the Si—H bond in the gate insulating layer 22.

The semiconductor device 1 includes the trench gate structure 20 having the gate trench 21, the gate insulating layer 22 and the gate electrode 23. The opening portion 53 of the barrier electrode 51 overlaps at least one (all in this embodiment) of the gate trench 21, the gate insulating layer 22, and the gate electrode 23 in a plan view. With this structure, the distance between the gate insulating layer 22 and the opening portion 53 can be shortened. The hydrogen ions can thereby be appropriately introduced through the opening portion 53 into the gate insulating layer 22 and therefore the Si—H bond can be appropriately formed in the gate insulating layer 22.

The opening portions 53 of the barrier electrode 51 preferably has the width W2 smaller than the opening width W1 of the gate trench 21. With this structure, it is possible to expand a margin with respect to a misalignment of the opening portion 53. Therefore, the opening portion 53 can be appropriately formed in the region between mutually adjacent ones of the plurality of contact openings 42 on the intermediate insulating layer 41.

The intermediate insulating layer 41 is preferably formed of the material that allows the hydrogen ions to be passed through. The hydrogen ions can thereby be introduced efficiently through the intermediate insulating layer 41 into the gate insulating layer 22. The gate electrode 23 is preferably formed of the electrode material that allows the hydrogen ions to be passed through. The hydrogen ions can thereby be introduced efficiently through the gate electrode 23 into the gate insulating layer 22. The main electrode 52 is preferably formed of the electrode material that allows the hydrogen ions to be passed through. The hydrogen ions can thereby be introduced efficiently through the main electrode 52 into the gate insulating layer 22.

The crystal defect region 13 serves as at least one of a lifetime killer region, a buffer region and a field stop region, and the structure with the gate insulating layer 22 including the Si—H bond in the insulator is particularly effective for the structure in which the crystal defect region 13 serves as the lifetime killer region. The lifetime killer region is effective in shortening the turn-off time and thereby highly compatible with IGBT. Therefore, the semiconductor device 1 thus having the crystal defect region 13 that serves as a lifetime killer region can improve the high reliability of the gate insulating layer 22 while shortening the turn-off time.

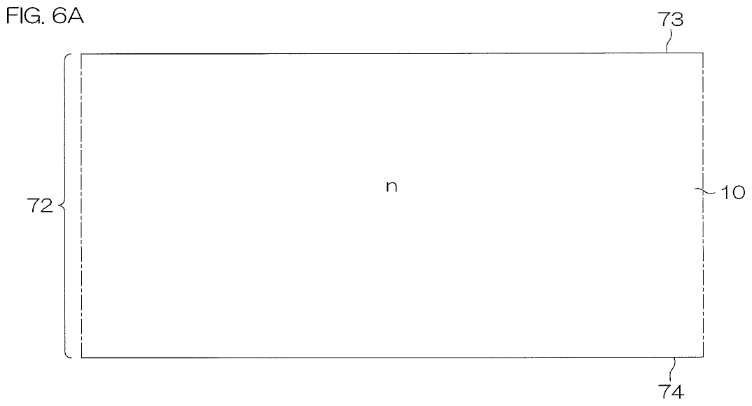

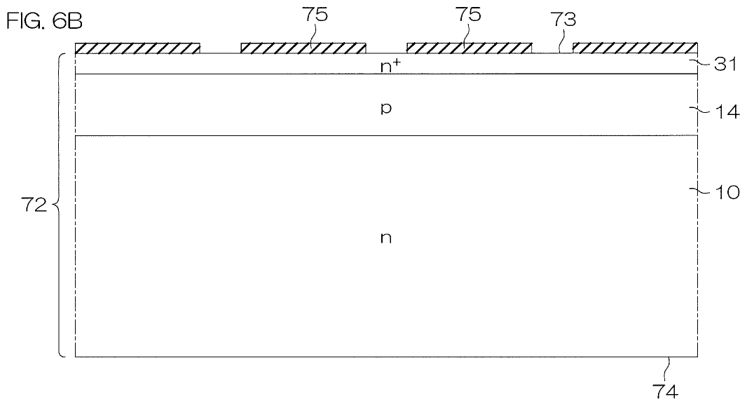

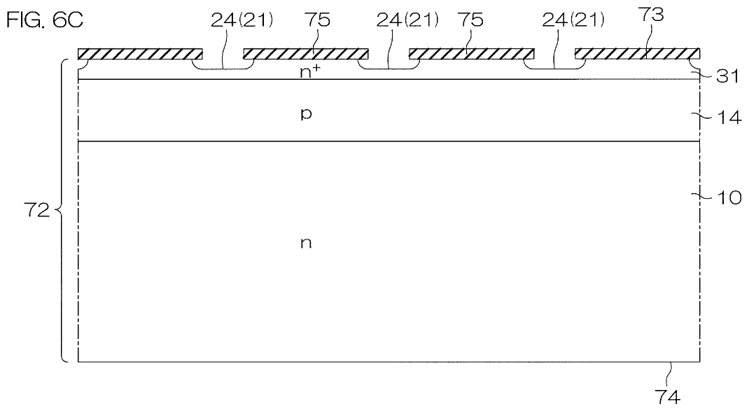

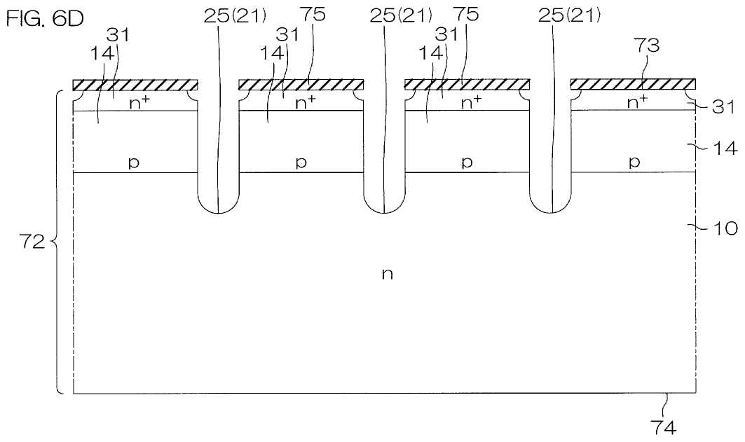

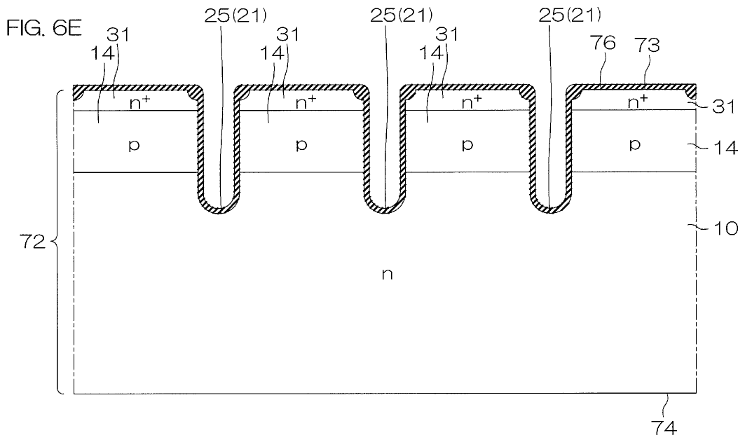

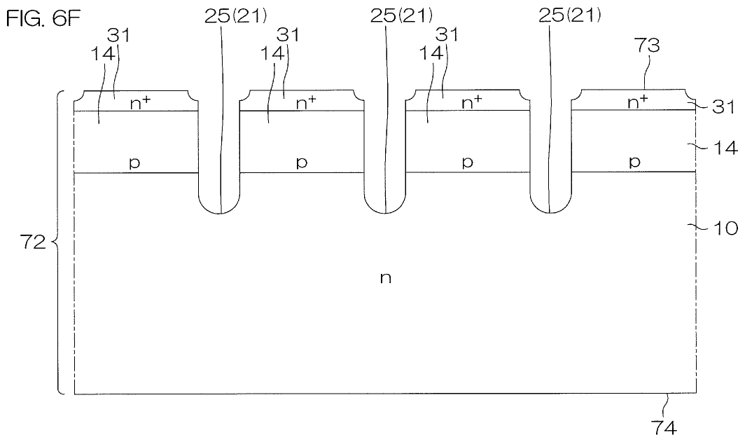

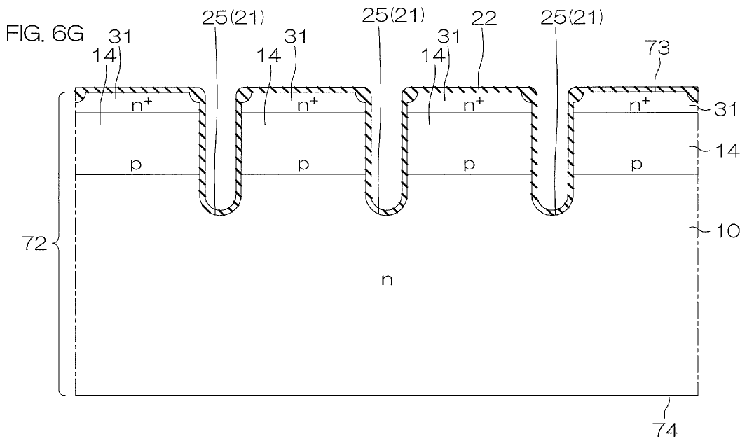

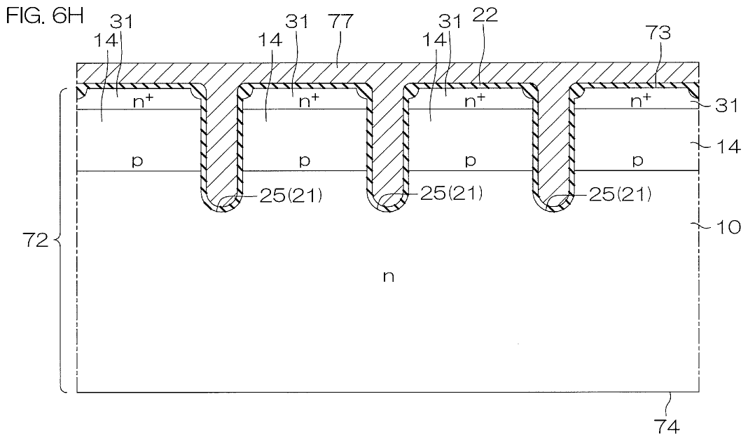

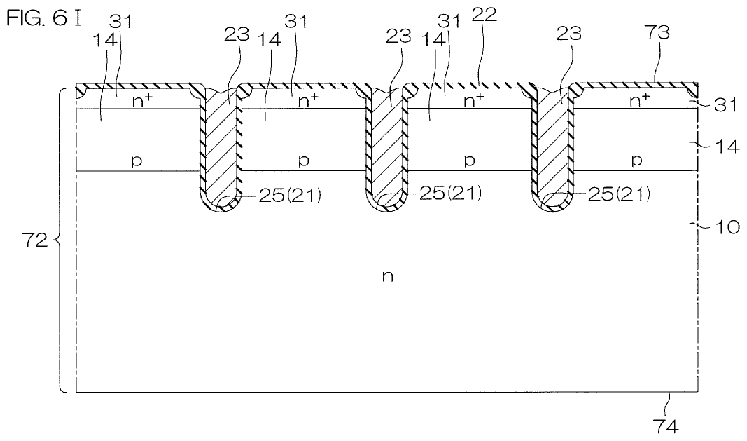

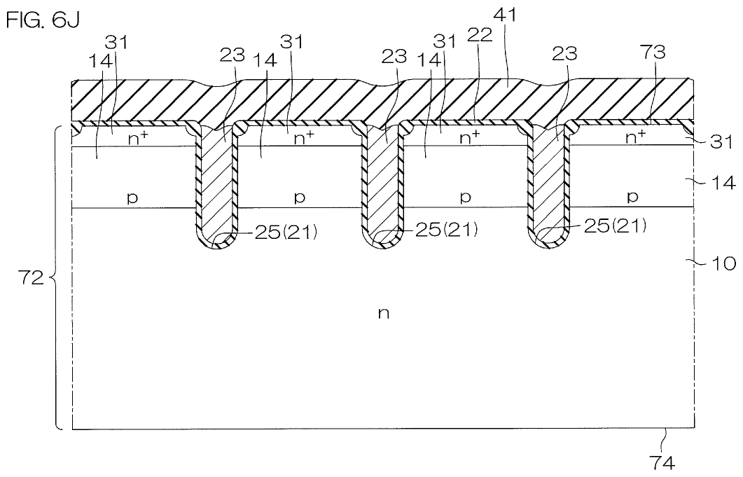

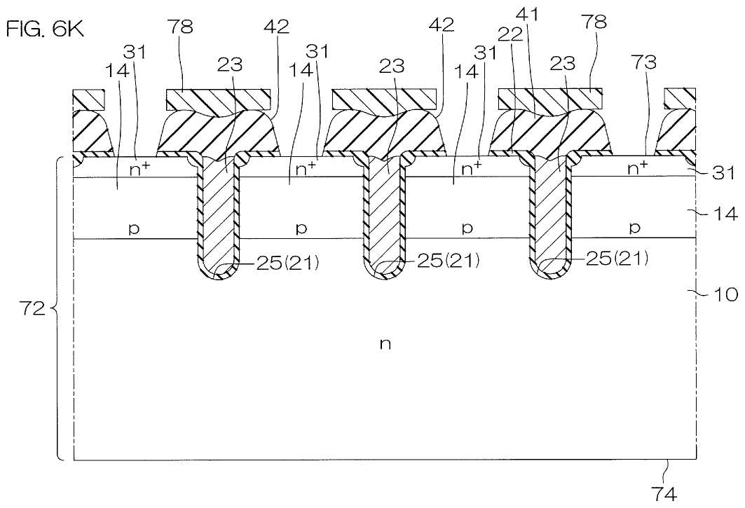

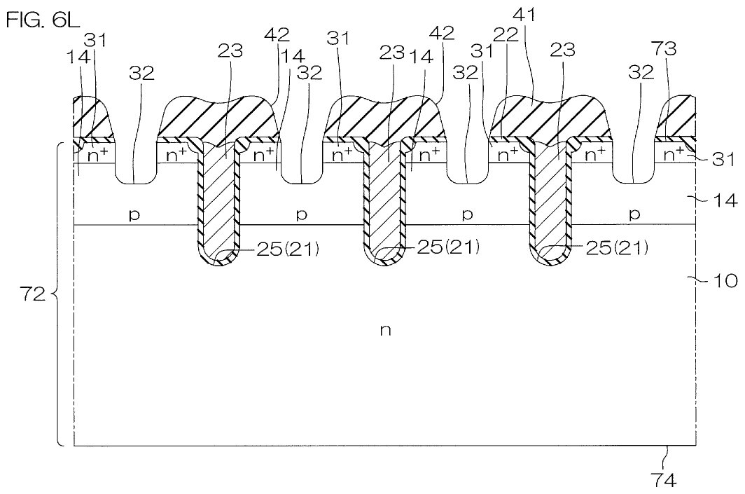

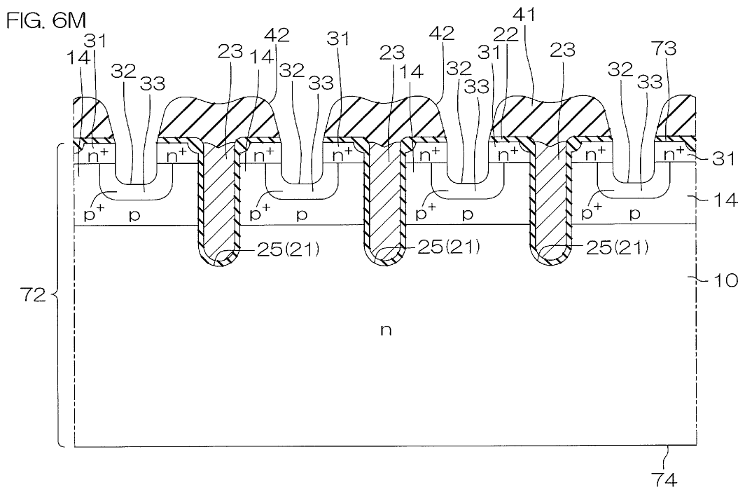

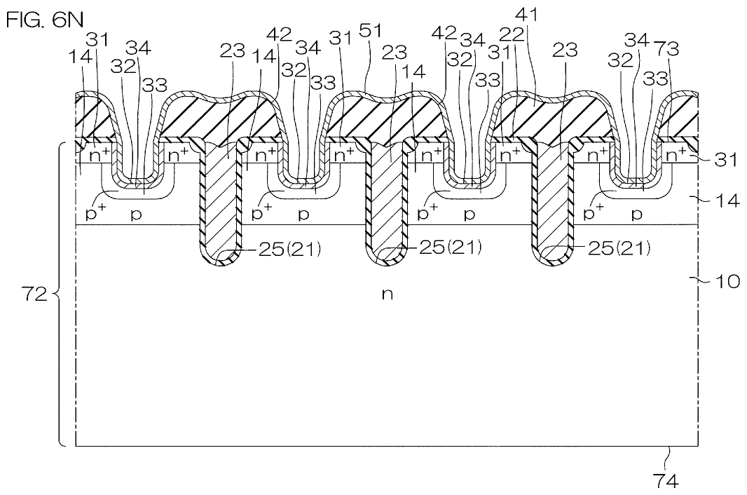

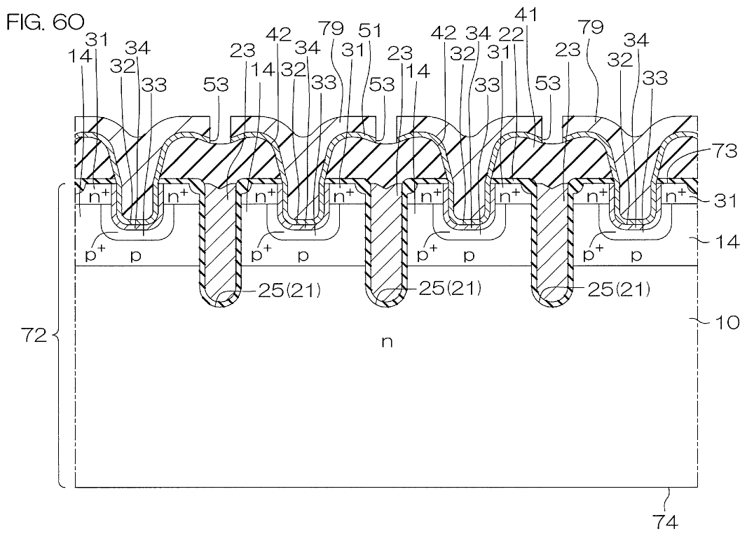

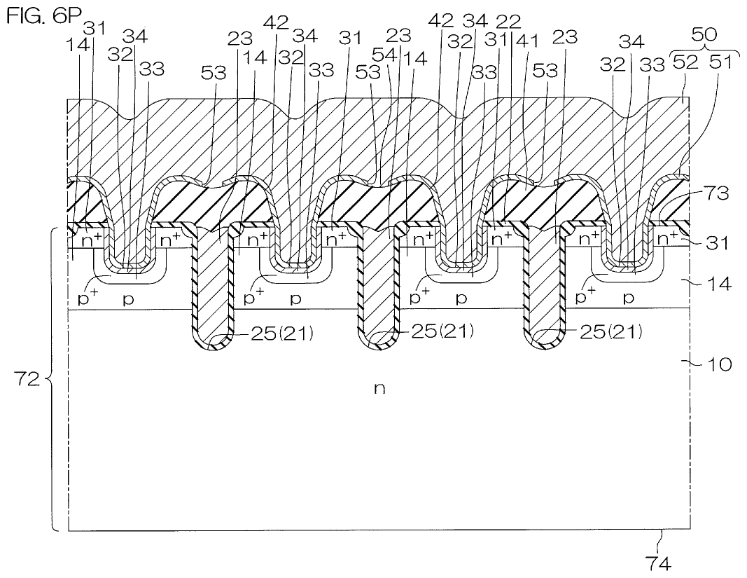

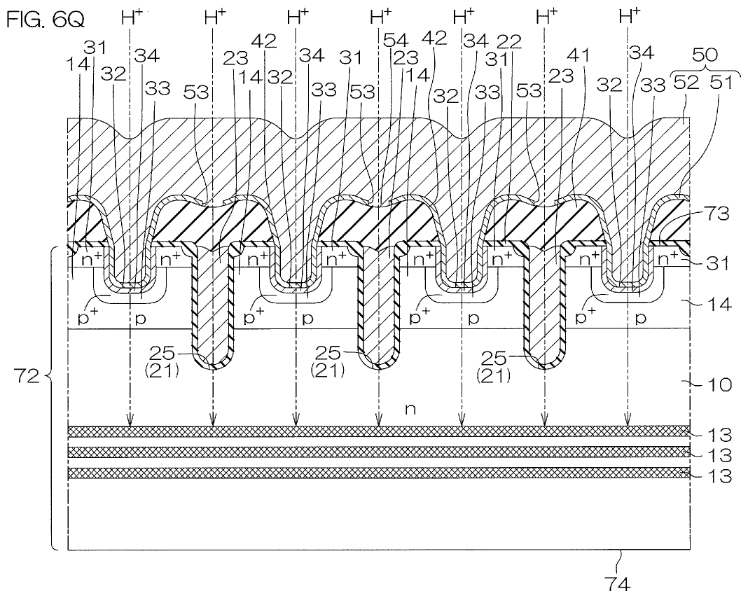

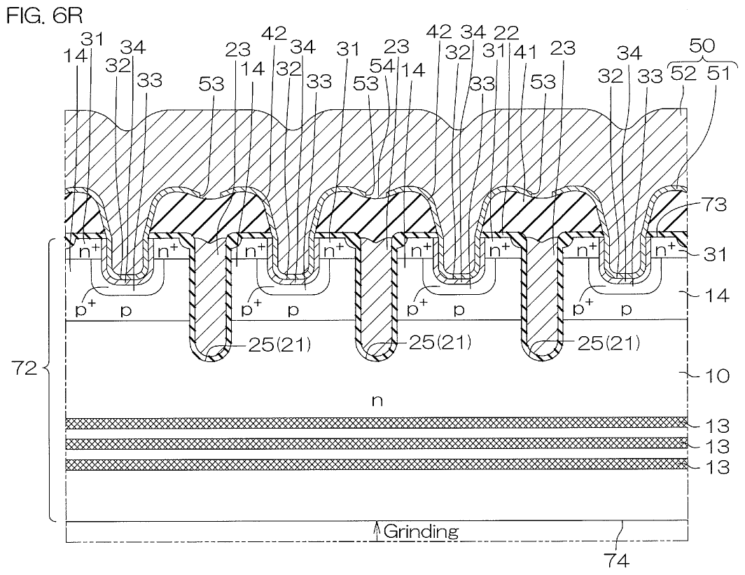

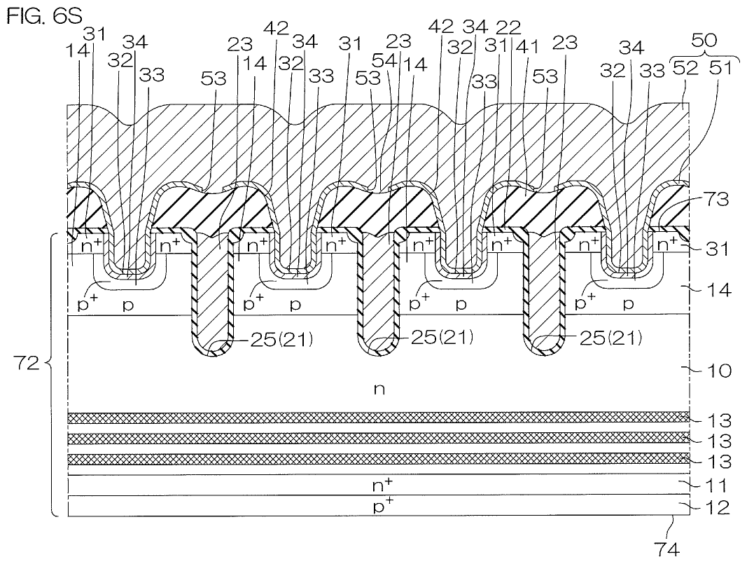

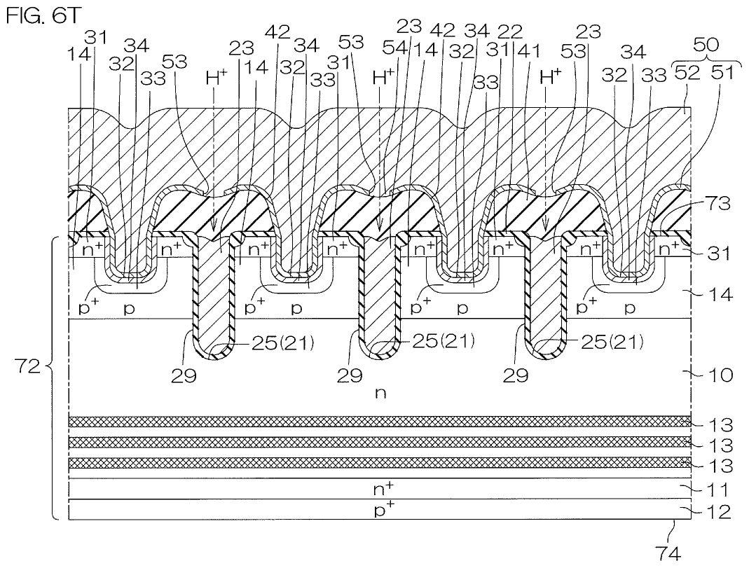

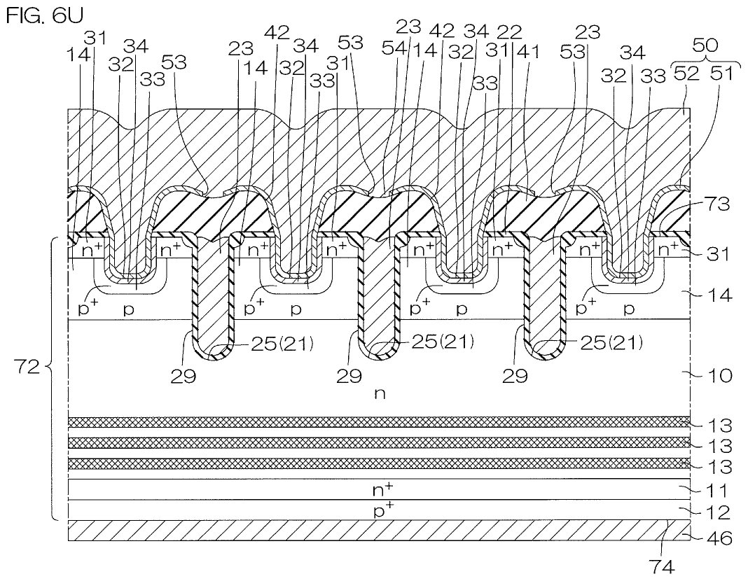

FIGS. 6A to 6U are cross-sectional views for illustrating an example of a manufacturing method for the semiconductor device 1 shown in FIG. 1.

Referring to FIG. 6A, a silicon-made wafer 72 is prepared as a base of a semiconductor layer 2. The wafer 72 may have a single-layer structure composed of an FZ wafer that is formed by an FZ method or a CZ wafer that is formed by a CZ method. In any of the FZ and CZ wafer cases, the wafer 72 contains oxygen at a predetermined density. An oxygen density of the wafer 72 may be 1×10¹⁵ cm⁻³ or more and 1×10¹⁹ cm⁻³ or less.

The wafer 72 has a first wafer main surface 73 on one side and a second wafer main surface 74 on the other side. The first wafer main surface 73 and the second wafer main surface 74 correspond to the first main surface 3 and the second main surface 4 of the semiconductor layer 2, respectively.

Next, referring to FIG. 6B, a body region 14 and an emitter region 31 are formed in a surface layer portion of the first wafer main surface 73. The body region 14 is formed by selectively introducing p-type impurities into the surface layer portion of the first wafer main surface 73 by an ion implantation method via an ion implantation mask (not shown) . The emitter region 31 is formedby selectively introducing n-type impurities into a surface layer portion of the body region 14 by an ion implantation method through via ion implantation mask (not shown).

Next, a hard mask 75 having a predetermined pattern is formed on the first wafer main surface 73. The hard mask 75 exposes regions in which the plurality of gate trenches 21 are to be formed and covers the other regions. The hard mask 75 may be formed by a thermal oxidation treatment method or a CVD (Chemical Vapor Deposition) method. The hard mask 75 may be patterned by a wet etching method or a dry etching method.

Next, referring to FIG. 6C, the first trench portions 24 of the gate trenches 21 are formed in the first wafer main surface 73. The first trench portions 24 are formed by digging down the first wafer main surface 73 exposed from the hard mask 75 by an etching method. The etching method is preferably an isotropic wet etching method or an isotropic dry etching method.

Next, referring to FIG. 6D, the second trench portions 25 of gate trenches 21 are formed in the first wafer main surface 73. The second trench portions 25 are formed by digging down bottom walls of the first trench portions 24 exposed from the hard mask 75 by an etching method. The etching method is preferably an anisotropic wet etching method or an anisotropic dry etching method. After forming the gate trenches 21, the hard mask 75 is removed.

Next, referring to FIG. 6E, a sacrificial oxidation layer 76 is formed on the first wafer main surface 73. The sacrificial oxidation layer 76 is formed as a film along the inner walls of the gate trenches 21 and the first wafer main surface 73. The sacrificial oxidation layer 76 is formed by a thermal oxidation treatment method.

Next, referring to FIG. 6F, the sacrificial oxidation layer 76 is removed by an etching method. The etching method may be a wet etching method and/or a dry etching method. Therefore, the inner walls of the gate trenches 21 are smoothened. The steps of forming and removing the sacrificial oxidation layer 76 may be skipped as appropriate. However, the steps of forming and removing the sacrificial oxidation layer 76 are preferably performed in view of the characteristics of the gate insulating layer 22.

Next, referring to FIG. 6G, the gate insulating layer 22 is formed on the first wafer main surface 73. The gate insulating layer 22 is formed as a film along the inner walls of the gate trenches 21 and the first wafer main surface 73. The gate insulating layer 22 is formed by a thermal oxidation treatment method or a CVD method. In this embodiment, the gate insulating layer 22 is formed by the thermal oxidation treatment method.

Next, referring to FIG. 6H, a base electrode layer 77 is formed on the first wafer main surface 73 as a base of the gate electrode 23. The base electrode layer 77 is composed of the electrode material that allows the hydrogen ions to be passed through. In this embodiment, the base electrode layer 77 is composed of the conductive polysilicon layer. The base electrode layer 77 is preferably composed of the n-type polysilicon layer. The base electrode layer 77 is buried in the gate trench 21 with the gate insulating layer 22 interposed therebetween and covers the first wafer main surface 73 with the gate insulating layer 22 interposed therebetween. The base electrode layer 77 may be formed by a CVD method.

Next, referring to FIG. 61, unnecessary portions of the base electrode layer 77 are removed by an etching method. The unnecessary portions of the base electrode layer 77 are removed until the gate insulating layer 22 is exposed. The etching method may be a wet etching method and/or a dry etching method. The gate electrodes 23 are thereby be formed in the gate trenches 21.

Next, referring to FIG. 6J, the intermediate insulating layer 41 is formed on the first wafer main surface 73. The intermediate insulating layer 41 is composed of the insulator that allows the hydrogen ions to be passed through. The intermediate insulating layer 41 may have a single-layer structure or a laminated structure including one or both of an SiO₂ layer and an SiN layer. The intermediate insulating layer 41 may have a laminated structure including a plurality of SiO₂ layers. The intermediate insulating layer 41 may include at least one of a USG layer, a PSG layer, and a BPSG layer as an example of the SiO₂ layer . The intermediate insulating layer 41 may be formed by a CVD method.

Next, referring to FIG. 6K, a resist mask 78 having a predetermined pattern is formed on the intermediate insulating layer 41. The resist mask 78 exposes regions in which the plurality of contact openings 42 are to be formed in the intermediate insulating layer 41 and covers the other regions.

Next, unnecessary portions of the intermediate insulating layer 41 and unnecessary portions of the gate insulating layer 22 are removed via the resist mask 78 by an etching method. The etching method may be a wet etching method and/or a dry etching method. Therefore, the plurality of contact openings 42 from which the first wafer main surface 73 is exposed are formed in the intermediate insulating layer 41. In this step, the plurality of contact openings 42 from which the gate electrodes 23 are exposed are formed in the intermediate insulating layer 41, though not shown. The resist mask 78 is removed thereafter.

Next, referring to FIG. 6L, portions of the first wafer main surface 73 exposed from the plurality of contact openings 42 are removed by an etchingmethod. The etching method may be a wet etching method and/or a dry etching method. Therefore, the plurality of contact holes 32 in communication with the plurality of contact openings 42 are formed in the first wafer main surface 73. In the step of forming the contact holes 32, the above-mentioned resist mask 78 may be utilized to remove unnecessary portions of the first wafer main surface 73.

Next, referring to FIG. 6M, the contact regions 33 are formed in regions along the contact holes 32 in the surface layer portion of the body region 14. The contact regions 33 are formed by selectively introducing p-type impurities into the surface layer portion of the body region 14 by an ion implantation method via an ion implantation mask (not shown).

Next, referring to FIG. 6N, the barrier electrode 51 is formed on the intermediate insulating layer 41. The barrier electrode 51 is formed as a film along the main surface of the intermediate insulating layer 41, the inner walls of the contact openings 42, and the inner walls of the contact holes 32. The barrier electrode 51 contains the electrode material that allows the hydrogen ions to be absorbed.

In this step, the Ti layer 61 composed of the electrode material that allows the hydrogen ions to be absorbed is first formed. The Ti layer 61 may be formed by an evaporation method and/or a sputtering method. Next, the silicide layers 34 composed of the Ti silicide are formed at portions in contact with the Ti layer 61 in the first wafer main surface 73 by an RTA (Rapid Thermal Anneal) method. Next, the TiN layer 62 is formed on the Ti layer 61. The TiN layer 62 may be formed by an evaporation method and/or a sputtering method.

One or both of the Ti layer 63 and the W layer 64 may be formed on the TiN layer 62 according to the configuration examples shown in FIGs . 5A to 5D. Both of the Ti layer 63 and the W layer 64 are formed by an evaporation method and/or a sputtering method.

Next, referring to FIG. 60, a resist mask 79 having a predetermined pattern is formed on the barrier electrode 51 . The resist mask 79 exposes regions in which the plurality of opening portions 53 are to be formed in the barrier electrode 51 and covers the other regions. The regions in which the plurality of opening portions 53 are to be formed in the barrier electrode 51 are at least one of the portions covering the intermediate insulating layer 41 and the portions covering the semiconductor layer 2 in the barrier electrode 51. In this embodiment, the regions in which the plurality of opening portions 53 are to be formed in the barrier electrode 51 are the portions covering the intermediate insulating layer 41 in the barrier electrode 51.

Next, unnecessary portions of the barrier electrode 51 are removed via the resist mask 79 by an etching method. The etching method may be a wet etching method and/or a dry etching method. Therefore, the plurality of opening portions 53 from which at least one of portions of the intermediate insulating layer 41 and portions of the semiconductor layer 2 are exposed are formed in the barrier layer 51. In this step, the plurality of opening portions 53 from which portions of the intermediate insulating layer 41 are respectively exposed are formed. The specific form of the opening portions 53 has been mentioned above and will not be described here . The resist mask 79 is removed thereafter.

Next, referring to FIG. 6P, the main electrode 52 is formed on the barrier electrode 51. The main electrode 52 fills the contact openings 42, the contact holes 32 and the opening portions 53 via the barrier electrode 51 and covers the barrier electrode 51. The main electrode 52 is composed of the electrode material that allows the hydrogen ions to be passed through. The main electrode 52 may include at least one of a pure Al layer, an AlSi layer, an AlCu layer, and an AlSiCu layer. The main electrode 52 may be formed by an evaporation method and/or a sputtering method.

Next, unnecessary portions of the barrier electrode 51 and unnecessary portions of the main electrode 52 are removed via a resist mask having a predetermined pattern (not shown) by an etching method. Therefore, the gate main surface electrodes 47 and the emitter main surface electrodes 50 are formed.

Next, referring to FIG. 6Q, the single or the plurality of (plurality in this embodiment) crystal defect regions 13 are formed in the wafer 72. The plurality of crystal defect regions 13 are formed in regions closer to the second wafer main surface 74 than the first wafer main surface 73. Specifically, the plurality of crystal defect regions 13 are formed in regions closer to the second wafer main surface 74 than the bottom walls of the plurality of gate trenches 21. The plurality of crystal defect regions 13 are formed in a mutually spaced manner in the normal direction Z such as to extend in planes or in layers in directions parallel to the first wafer main surface 73.

The crystal defect regions 13 are formed by introducing crystal defects into the wafer 72 by one or both of an electron beam irradiation method and an ion irradiation method. In this step, the crystal defect regions 13 are formed in the wafer 72 through the gate insulating layer 22.

In the electron beam irradiation method, the wafer 72 is irradiated with electrons through the gate insulating layer 22 and thereby voids are introduced into the wafer 72.

In the ion irradiation method, the wafer 72 is irradiated with light element ions through the gate insulating layer 22 and thereby voids are introduced into the wafer 72. The light element ions may be protons or helium ions. The voids include point defects, holes, etc. to form dangling bonds of silicon.

In this step, the protons are introduced into the wafer 72 as an example of light element ions by an ion irradiation method. The protons are introduced stepwise into different positions in the thickness direction of the wafer 72. The amount of protons introduced into the wafer 72 and/or the acceleration voltage are adjusted according to the position and/or the defect density of crystal defect regions 13 to be formed. The proton acceleration voltage may be adjusted to be in a range equal to or higher than 1 MeV but equal to or lower than 20 MeV. The amount of protons introduced may be adjusted to be in a range of 1×10¹² cm⁻³ or more and 1×10¹⁵ cm⁻³ or less.

In the step of forming the crystal defect regions 13, electrons or light element ions (protons in this embodiment) pass through the structure on the first wafer main surface 73 including the gate insulating layer 22 to enter into the wafer 72. This results in that dangling bonds (i.e. voids) of silicon are formed in the gate insulating layer 22.

Next, the protons are diffused in the wafer 72 by a thermal treatment, and the voids in the crystal defect regions 13 are terminated by oxygen and protons. Therefore, the crystal defect regions 13 become the n-type impurity regions including the VOH defects composed of voids (V) , oxygen (O) and hydrogen (H) . The crystal defect regions 13 serve as at least one of the lifetime killer region, the buffer region, and the field stop region.

Next, referring to FIG. 6R, the wafer 72 is thinned to a desired thickness by grinding the second wafer main surface 74. The second wafer main surface 74 may be ground by a CMP (Chemical Mechanical Polishing) method. The step of grinding the second wafer main surface 74 may be skipped as appropriate.

Next, referring to FIG. 6S, the buffer region 11 is formed in a surface layer portion of the second wafer main surface 74 . The buffer region 11 is formed by introducing n-type impurities into the surface layer portion of the second wafer main surface 74 by an ion implantation method.

The collector region 12 is also formed in the surface layer portion of the second wafer main surface 74 . Specifically, the collector region 12 is formed in the surface layer portion of the second wafer main surface 74 side in the buffer region 11. The collector region 12 is formed by introducing p-type impurities into the surface layer portion of the second wafer main surface 74 by an ion implantation method. The step of forming the buffer region 11 and the step of forming the collector region 12 may be performed in any order. The buffer region 11 may be formed after forming the collector region 12.

Next, referring to FIG. 6T, hydrogen ions are introduced into the gate insulating layer 22 and dangling bonds of silicon atoms in the gate insulating layer 22 are hydrogen-terminated by the hydrogen ions. The dangling bonds of silicon atoms in the gate insulating layer 22 are formed due to the step of forming the crystal defect regions 13.

The hydrogen ions are introduced into the gate insulating layer 22 by a hydrogen annealing treatment method. In the hydrogen annealing treatment method, the wafer 72 is annealed in a high-temperature atmosphere containing hydrogen.

The hydrogen ions are introduced from the first wafer main surface 73 side into the gate insulating layer 22 . The hydrogen ions introduced into the gate insulating layer 22 are trapped (absorbed) by the barrier electrode 51 and, at the same time, introduced through the opening portions 53 of the barrier electrode 51 into the gate insulating layer 22.

Specifically, the hydrogen ions enter the opening portions 53 of the barrier electrode 51 and pass through the intermediate insulating layer 41 and are introduced into the gate insulating layer 22. More specifically, the hydrogen ions enter the opening portions 53 of the barrier electrode 51 and pass through the main electrode 52, the intermediate insulating layer 41 and the gate electrode 23 and are introduced into the gate insulating layer 22.

Therefore, the dangling bonds of silicon atoms in the gate insulating layer 22 are hydrogen-terminated by the hydrogen ions. In this step, the hydrogen ions are also introduced into the interface region 29 in contact with the gate insulating layer 22 in the first wafer main surface 73. Therefore, the dangling bonds of silicon atoms in the interface region 29 are hydrogen-terminated by the hydrogen ions.

Next, referring to FIG. 6U, the collector electrode 46 is formed on the second wafer main surface 74. The collector electrode 46 may include at least one of a Ti layer, an Ni layer, a Pd layer, an Au layer, an Ag layer, and an Al layer. The collector electrode 46 may be formed by an evaporation method and/or a sputtering method.

Subsequently, the wafer 72 is cut selectively such that a plurality of semiconductor devices 1 are cut out . The semiconductor devices 1 are thus manufactured through the steps including the foregoing steps.

As described above, the manufacturing method for the semiconductor device 1 includes the steps of forming the gate insulating layer 22 on the wafer 72, forming the crystal defect regions 13 in the wafer 72 after the step of forming the gate insulating layer 22, and introducing the hydrogen ions into the gate insulating layer 22 after the step of forming the crystal defect regions 13. With this manufacturing method, dangling bonds of silicon atoms in the gate insulating layer 22 can be hydrogen-terminated by the hydrogen ions.

In the gate insulating layer 22 including the dangling bonds of silicon atoms, the dangling bonds of silicon atoms serve as charge traps. Therefore, the insulating characteristics of the gate insulating layer 22 fluctuate over time. As an example, the gate threshold voltage fluctuates over time due to aging degradation of the gate insulating layer 22.

Therefore, in the manufacturing method for the semiconductor device 1, the dangling bonds of silicon atoms in the gate insulating layer 22 are hydrogen-terminated by the hydrogen ions after the step of forming the crystal defect regions 13. With this manufacturing method, the charge traps in the gate insulating layer 22 can be reduced and the aging degradation of the insulating characteristics can thereby be suppressed. The semiconductor device 1 including the highly reliable gate insulating layer 22 can thereby be manufactured and provided.

The manufacturing method for the semiconductor device 1 includes the step of hydrogen-terminating dangling bonds of silicon atoms in the wafer 72 with the hydrogen ions in the interface region 29 in contact with the gate insulating layer 22 in the wafer 72 . The aging variation of the insulating characteristics can thereby be appropriately suppressed.

The manufacturing method for the semiconductor device 1 includes the steps of forming the gate electrode 23, forming the intermediate insulating layer 41, forming the barrier electrode 51, and forming the opening portion 53 in the barrier electrode 51, before the step of introducing the hydrogen ions into the gate insulating layer 22.

The gate electrode 23 is formed on the gate insulating layer 22. The intermediate insulating layer 41 covers the gate electrode 23. The barrier electrode 51 contains the electrode material that allows the hydrogen ions to be absorbed and covers the intermediate insulating layer 41. The opening portion 53 of the barrier electrode 51 exposes a portion of the intermediate insulating layer 41 or a portion of the semiconductor layer 2. In this manufacturing method, the opening portion 53 of the barrier electrode 51 is formed to expose a portion of the intermediate insulating layer 41.

With the manufacturing method described above, the hydrogen ions introduced into the gate insulating layer 22 are trapped (absorbed) by the barrier electrode 51 and, at the same time, introduced through the opening portion 53 of the barrier electrode 51 into the gate insulating layer 22 . It is therefore possible to suppress absorption of the hydrogen ions by the barrier electrode 51 and appropriately form the Si—H bond in the gate insulating layer 22.

The manufacturing method for the semiconductor device 1 includes the steps of, forming the gate trench 21, forming the gate insulating layer 22, and forming the gate electrode 23, before the step of introducing the hydrogen ions into the gate insulating layer 22. In the step of forming the opening portion 53, the opening portion 53 which overlaps at least one (all in this embodiment) of the gate trench 21, the gate insulating layer 22 and the gate electrode 23 in a plan view is formed. With this manufacturing method, the distance between the gate insulating layer 22 and the opening portion 53 can be shortened. Therefore, the hydrogen ions can be appropriately introduced through the opening portion 53 into the gate insulating layer 22.

In the step of forming the opening portion 53, the opening portion 53 is preferably formed to have the width W2 smaller than the opening width W1 of the gate trench 21. With this manufacturing method, it is possible to expand a margin with respect to a misalignment of the opening portion 53. Therefore, the opening portion 53 can be appropriately formed in a region between mutually adjacent ones of the plurality of contact openings 42 on the intermediate insulating layer 41.

In the manufacturing method for the semiconductor device 1, the intermediate insulating layer 41 is preferably formed of the material that allows the hydrogen ions to be passed through. The hydrogen ions can thereby be introduced efficiently through the intermediate insulating layer 41 into the gate insulating layer 22. The gate electrode 23 is preferably formed of the electrode material that allows the hydrogen ions to be passed through. The hydrogen ions can thereby be introduced efficiently through the gate electrode 23 into the gate insulating layer 22. The main electrode 52 is preferably formed of the electrode material that allows the hydrogen ions to be passed through. The hydrogen ions can thereby be introduced efficiently through the main electrode 52 into the gate insulating layer 22.

In the manufacturing method for the semiconductor device 1, an example in which the steps of forming the body region 14 and the emitter region 31 (see FIG. 6B, etc.) are performed before the step of forming the gate trench 21 (see FIGS. 6C and 6D) has been described. However, the steps of forming the body region 14 and the emitter region 31 do not necessarily have to be performed at this timing, and may be performed at any timing before the step of forming the intermediate insulating layer 41 (see FIG. 6J).

In the manufacturing method for the semiconductor device 1, an example in which the step of forming the crystal defect region 13 (see FIG. 6Q) is performed after the step of forming the main electrode 52 (see FIG. 6P) and before the step of forming the collector region 12 (buffer region 11) (see FIG. 6S) has been described. However, the step of forming the crystal defect region 13 (see FIG. 6Q) does not necessarily have to be performed at this timing, and may be performed at any timing after the step of forming the gate insulating layer 22 (see FIG. 6G) and before the step of introducing the hydrogen ions into the gate insulating layer 22 (see FIG. 6T).

In the manufacturing method for the semiconductor device 1, an example in which the step of introducing the hydrogen ions into the gate insulating layer 22 (see FIG. 6T) is performed after the step of forming the collector region 12 (buffer region 11) (see FIG. 6S) has been described. However, the step of forming the collector electrode 46 (see FIG. 6U) does not necessarily have to be performed at this timing, and may be performed at any timing after the step of forming the crystal defect region 13 (see FIG. 6Q) and before the step of cutting the wafer 72 (see FIG. 6U).

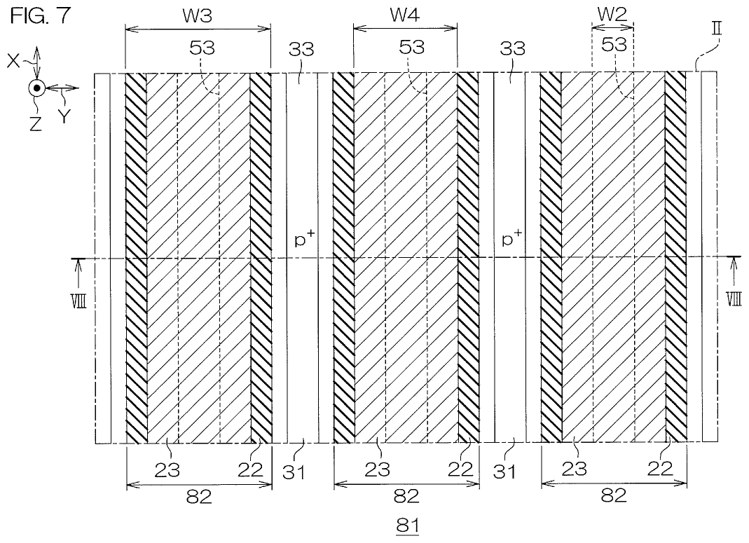

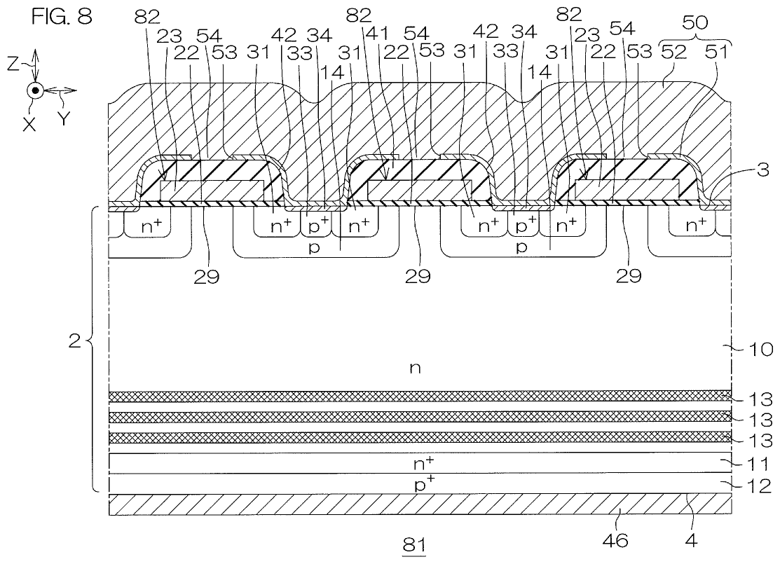

FIG. 7 is an enlarged view corresponding to FIG. 2 and showing a semiconductor device 81 according to a second embodiment of the present invention. FIG. 8 is a cross-sectional view taken along a line VIII-VIII shown in FIG. 7. Structures corresponding to those described for the semiconductor device 1 will hereinafter be designated by the same reference signs to omit description thereof.

Referring to FIGS. 7 and 8, the semiconductor device 81 includes a plurality of body regions 14 formed in a surface layer portion of the first main surface 3 of the semiconductor layer 2 in the device region 6. In this embodiment, the plurality of body regions 14 are each formed in a band shape extending in the first direction X and spaced from each other in the second direction Y in a manner such that portions of the drift region 10 are exposed therebetween. Therefore, the plurality of body regions 14 are formed in a stripe pattern extending along the first direction X in a plan view. The plurality of body regions 14 oppose the crystal defect regions 13 in the normal direction Z.

In this embodiment, the semiconductor device 81 includes a plurality of planar gate structures 82 instead of the trench gate structures 20. The plurality of planar gate structures 82 are formed on the first main surface 3 of the semiconductor layer 2 in the device region 6. The plurality of planar gate structures 82 are each formed in a band shape extending in the first direction X and spaced from each other in the second direction Y.

Therefore, the plurality of planar gate structures 82 are formed in a stripe pattern extending along the first direction X in a plan view. The plurality of planar gate structures 82 oppose the crystal defect regions 13 in the normal direction Z. The planar gate structures 82 are each formed in a manner of bridging between two adjacent ones of the body regions 14 and covering the portion of the drift region 10 exposed from the region between the two adjacent body regions 14.

Each of the planar gate structures 82 includes the gate insulating layer 22 (insulating layer) and the gate electrode 23 (electrode) . The gate insulating layer 22 covers the first main surface 3. Specifically, the gate insulating layer 22 bridges between two adjacent ones of the body regions 14 and covers the portion of the drift region 10 exposed from the region between the two adjacent body regions 14.

The gate insulating layer 22 has the same structure as the gate insulating layer 22 according to the first embodiment . That is, the gate insulating layer 22 is composed of the insulator containing silicon. The gate insulating layer 22 preferably includes at least one type of the SiO₂ layer, the SiN layer, the SiON layer, the HfSiO layer and the HfSiON layer. The gate insulating layer 22 may have a single-layer structure composed of the SiO₂ layer, the SiN layer, the SiON layer, the HfSiO layer or the HfSiON layer. The gate insulating layer 22 may have a laminated structure in which at least two layers of the

SiO₂ layer, the SiN layer, the SiON layer, the HfSiO layer and the HfSiON layer are laminated in any order . In this embodiment, the gate insulating layer 22 has a single-layer structure composed of the SiO₂ layer.

The gate insulating layer 22 includes the Si—H bond in which the dangling bonds of silicon atoms are hydrogen-terminated by the hydrogen ions, in the insulator. The gate insulating layer 22 preferably has the outer surface including the Si—H bond in which dangling bonds of silicon atoms are hydrogen-terminated by the hydrogen ions.

The thickness of the gate insulating layer 22 may be 10 nm or more and 1000 nm or less. The thickness of the gate insulating layer 22 maybe 10 nm or more and 50 nm or less, 50 nm or more and 100 nm or less, 00 nm or more and 150 nm or less, 150 nm or more and 200 nm or less, 200 nm or more and 400 nm or less, 400 nm or more and 600 nm or less, 600 nm or more and 800 nm or less, 800 nm or more and 1000 nm or less. The thickness of the gate insulating layer 22 is preferably 20 nm or more and 200 nm or less.

In the structure described above, the semiconductor device 81 includes the interface region 29 covered with the gate insulating layer 22 in the semiconductor layer 2. The interface region 29 preferably has the Si—H bond in which dangling bonds of silicon atoms in the semiconductor layer 2 are hydrogen-terminated by the hydrogen ions.

The gate electrode 23 covers the gate insulating layer 22. Specifically, the gate electrode 23 is formed in a manner of bridging between two adjacent ones of the body regions 14 and covering the portion of the drift region 10 exposed from the region between the two adjacent body regions 14. The gate electrode 23 has a width W3 smaller than a width W4 of the gate insulating layer 22 . The gate electrode 23 is formed in a manner spaced inward from the peripheral edge of the gate insulating layer 22 such that the peripheral edge of the gate insulating layer 22 is exposed.

The semiconductor device 81 includes the plurality of n⁺-type emitter regions 31 formed in surface layer portions of the plurality of body regions 14, respectively. In this embodiment, two emitter regions 31 are formed in the surface layer portion of each body region 14. The two emitter regions 31 are each formed in a band shape extending in the first direction X and spaced from each other in the second direction Y in the surface layer portion of each body region 14.

The bottom portion of each emitter region 31 is positioned in a region between the first main surface 3 and the bottom portion of each body region 14. Each emitter region 31 is formed in a manner spaced inward from an edge portion of each body region 14 . Each emitter region 31 opposes a portion the gate electrode 23 with the gate insulating layer 22 interposed therebetween. Each emitter region 31 forms the channel region of the IGBT with the drift region 10 in each body region 14. The channel region is formed in a region in each body region 14 along the gate insulating layer 22.

The semiconductor device 81 includes a plurality of p⁺-type contact regions 33 formed in surface layer portions of the plurality of body regions 14, respectively. One or a plurality of contact regions 33 may be formed in the surface layer portion of each body region 14. Each contact region 33 is formed in a region between the two mutually adjacent emitter regions 31 in each body region 14. The bottom portion of each contact region 33 is positioned in a region between the first main surface 3 and the bottom portion of each body region 14.

The semiconductor device 81 includes the plurality of silicide layers 34 formed in surface layer portions of the plurality of body regions 14, respectively. Each silicide layer 34 is formed in a region between the mutually adjacent planar gate structures 82 in the surface layer portion of each body region 14. Each silicide layer 34 is electrically connected to the two emitter regions 31 and the contact region 33 in each body region 14. Each silicide layer 34 forms the ohmic contact with the corresponding emitter regions 31 and the contact region 33.

The semiconductor device 81 includes the intermediate insulating layer 41 covering the first main surface 3 of the semiconductor layer 2. The intermediate insulating layer 41 collectively covers the plurality of planar gate structures 82. That is, the intermediate insulating layer 41 collectively covers the gate insulating layer 21 and the gate electrode 23.

The intermediate insulating layer 41 includes the plurality of contact openings 42. The plurality of contact openings 42 include the contact openings 42 (not shown) from which the gate electrodes 23 are exposed. The plurality of contact openings 42 include the contact openings 42 from which the corresponding emitter regions 31 and the corresponding contact region 33 are exposed respectively in a region between ones of the plurality of planar gate structures 82. The plurality of contact openings 42 each formed between ones of the plurality of planar gate structures 82 are formed in band shapes extending along the planar gate structures 82 in a plan view.

The semiconductor device 81 includes the gate main surface electrode 47 and the emitter main surface electrode 50 formed on the intermediate insulating layer 41. The gate main surface electrode 47 has the same structure as in the above-mentioned first embodiment. The emitter main surface electrode 5 enters the plurality of contact openings 42 from above the intermediate insulating layer 41. The emitter main surface electrode 50 is electrically connected to the body region 14, the emitter regions 31 and the contact region 33 in each of the plurality of contact openings 42.

Specifically, the emitter main surface electrode 50 has the laminated structure including the barrier electrode 51 and the main electrode 52 laminated in this order from the intermediate insulating layer 41 side. The gate main surface electrode 47 also has the laminated structure including the barrier electrode 51 and the main electrode 52, though not shown . The structure of the emitter main surface electrode 50 will hereinafter be described, while the structure of the gate main surface electrode 47 will not be described.

The barrier electrode 51 is formed as a film along the main surface of the intermediate insulating layer 41 and the inner walls of the contact openings 42. The barrier electrode 51 defines recessed spaces in the contact openings 42. The barrier electrode 51 is electrically connected to the silicide layers 34 in the contact openings 42.

The barrier electrode 51 contains the electrode material that allows the hydrogen ions to be absorbed. The barrier electrode 51 contains hydrogen ions therein. In this embodiment, the barrier electrode 51 contains the Ti (titanium) as an example of the hydrogen ion absorbing electrode material. The structure of the barrier electrode 51 is applied with one of the above-mentioned forms shown in FIGS. 5A to 5D.

The barrier electrode 51 has the opening portion 53 from which at least one of a portion of the intermediate insulating layer 41 and a portion of the semiconductor layer 2 is exposed. In this embodiment, the barrier electrode 51 has the plurality of opening portions 53. In this embodiment, each of the opening portions 53 exposes a portion of the intermediate insulating layer 41. Each of the opening portions 53 forms the introduction path for hydrogen ions.

It is further preferable that each opening portion 53 overlaps one or both of the gate insulating layer 22 and the gate electrode 23 in a plan view. It is particularly preferable that each opening portion 53 overlaps the gate insulating layer 22 and the gate electrode 23 in a plan view. That is, each opening portion 53 preferably overlaps each planar gate structure 82 in a plan view.

In this embodiment, each opening portion 53 is formed in a band shape extending along each planar gate structure 82 in a plan view. The plurality of opening portions 53 may be formed in a manner spaced from each other such as to overlap one of the planar gate structures 82 in a plan view.

Referring to FIG. 7, each opening portion 53 preferably has the width W2 smaller than the width W3 of the gate insulating layer 22. Each opening portion 53 is preferably positioned in a region inside the peripheral edge of the gate insulating layer 22 in a plan view. Each opening portion 53 may have the width W2 smaller than the width W4 of the gate electrode 23. Each opening portion 53 may be positioned in a region inside the peripheral edge of the gate electrode 23 in a plan view.

Therefore, each opening portion 53 entirely overlaps the gate insulating layer 22 and the gate electrode 23 in a plan view. Each opening portion 53 may have the width W2 equal to or greater than the width W4 of the gate electrode 23 . Each opening portion 53 may be formed in a manner surrounding the gate electrode 23 in a plan view.

The main electrode 52 fills the recessed spaces defined by the barrier electrode 51 in the contact openings 42 and covers the barrier electrode 51. The main electrode 52 enters into the opening portions 53 of the barrier electrode 51 to be in contact with portions of the intermediate insulating layer 41 or portions of the semiconductor layer 2. In this embodiment, the main electrode 52 enters into the opening portions 53 of the barrier electrode 51 and has buried portions 54 connected to the intermediate insulating layer 41. The buried portions 54 of the main electrode 52 are formed in shapes corresponding to the opening portions 53 of the barrier electrode 51.

As described above, the semiconductor device 81 includes the semiconductor layer 2, the crystal defect region 13 and the gate insulating layer 22 . The crystal defect region 13 is formed in the semiconductor layer 2 . The gate insulating layer 22 is composed of an insulator containing silicon and includes the Si—H bond in which dangling bonds of silicon atoms are hydrogen-terminated by the hydrogen ions, in the insulator.

In the gate insulating layer 22 including dangling bonds of silicon atoms, the dangling bonds of silicon atoms serve as charge traps. Therefore, the insulating characteristics of the gate insulating layer 22 fluctuate over time. As an example, the gate threshold voltage fluctuates over time due to aging degradation of the gate insulating layer 22.

Therefore, in this embodiment, the dangling bonds of silicon atoms in the gate insulating layer 22 are hydrogen-terminated by the hydrogen ions. With this structure, the charge traps in the gate insulating layer 22 can be reduced, and the aging degradation of the insulating characteristics can thereby be suppressed. The semiconductor device 81 including the highly reliable gate insulating layer 22 can thereby be provided.

In the structure described above, the semiconductor device 81 includes the interface region 29 covered with the gate insulating layer 22 in the semiconductor layer 2. The interface region 29 has the Si—H bond in which dangling bonds of silicon atoms in the semiconductor layer 2 are hydrogen-terminated by the hydrogen ions. With this structure, the aging degradation of the insulating characteristics can be appropriately suppressed.

The semiconductor device 81 includes the gate electrode 23, the intermediate insulating layer 41 and the barrier electrode 51. The gate electrode 23 is formed on the gate insulating layer 22. The intermediate insulating layer 41 covers the gate electrode 23. The barrier electrode 51 contains the electrode material that allows the hydrogen ions to be absorbed. That is, the barrier electrode 51 contains the hydrogen ions therein. The barrier electrode 51 covers the intermediate insulating layer 41 and has the opening portion 53 from which a portion of the intermediate insulating layer 41 or a portion of the semiconductor layer 41 is exposed. In this embodiment, a portion of the intermediate insulating layer 41 is exposed from the opening portion 53.

With the structure described above, since the hydrogen ions are introduced through the opening portion 53 of the barrier electrode 51 into the gate insulating layer 22 during formation of the Si—H bond in the gate insulating layer 22, absorption of the hydrogen ions by the barrier electrode 51 can be suppressed. It is therefore possible to appropriately form the Si—H bond in the gate insulating layer 22.

The semiconductor device 81 includes the planar gate structure 82 having the gate insulating layer 22 and the gate electrode 23. The opening portion 53 of the barrier electrode 51 overlaps at least one (all in this embodiment) of the gate insulating layer 22 and the gate electrode 23 in a plan view. With this structure, the distance between the gate insulating layer 22 and each opening portion 53 can be shortened. Therefore, the hydrogen ions can be appropriately introduced through the opening portion 53 into the gate insulating layer 22 and the Si-H bond can thereby be appropriately formed in the gate insulating layer 22.

The opening portion 53 of the barrier electrode 51 preferably has the width W2 smaller than the width W3 of the gate insulating layer 22. The opening portion 53 is preferably positioned in a region inside the peripheral edge of the gate insulating layer 22 in a plan view. With this structure, it is possible to expand a margin with respect to a misalignment of each opening portion 53. Therefore, the opening portion 53 can be appropriately formed in a region between mutually adjacent ones of the plurality of contact openings 42 on the intermediate insulating layer 41.

The opening portion 53 of the barrier electrode 51 may have the width W2 smaller than the width W4 of the gate electrode 23. The opening portion 53 may be positioned in a region inside the peripheral edge of the gate electrode 23 in a plan view. With this structure, it is possible to reliably expand margin with respect to a misalignment of each opening portion 53.

The intermediate insulating layer 41 is preferably formed of the material that allows the hydrogen ions to be passed through. Therefore, the hydrogen ions can be introduced efficiently through the intermediate insulating layer 41 into the gate insulating layer 22. The gate electrode 23 is preferably formed of the electrode material that allows the hydrogen ions to be passed through. Therefore, the hydrogen ions can be introduced efficiently through the gate electrode 23 into the gate insulating layer 22. The main electrode 52 is preferably formed of the electrode material that allows the hydrogen ions to be passed through. Therefore, the hydrogen ions can be introduced efficiently through the main electrode 52 into the gate insulating layer 22.

The crystal defect region 13 serves as at least one of a lifetime killer region, a buffer region, and a field stop region, and the structure with the gate insulating layer 22 including the Si—H bond in the insulator is particularly effective for the structure in which the crystal defect region 13 serves as the lifetime killer region. The lifetime killer region is effective in shortening the turn-off time and thereby highly compatible with IGBT. Accordingly, the semiconductor device 81 thus having the crystal defect region 13 that serves as the lifetime killer region can improve the high reliability of the gate insulating layer 22 while shortening the turn-off time.

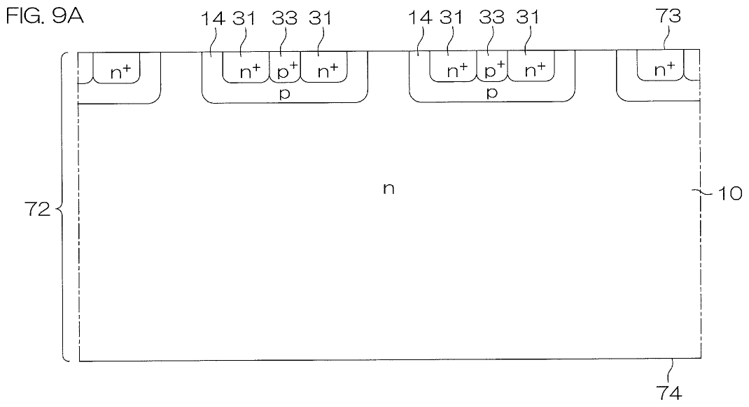

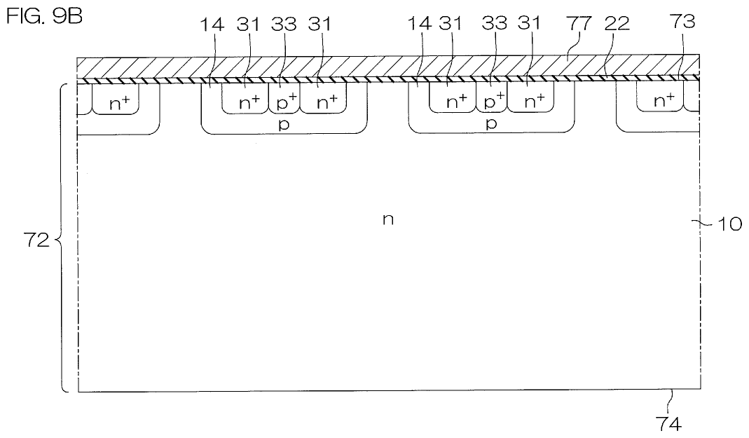

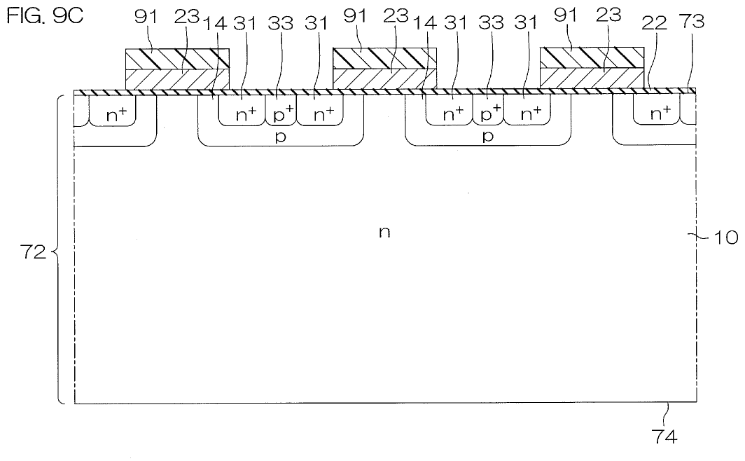

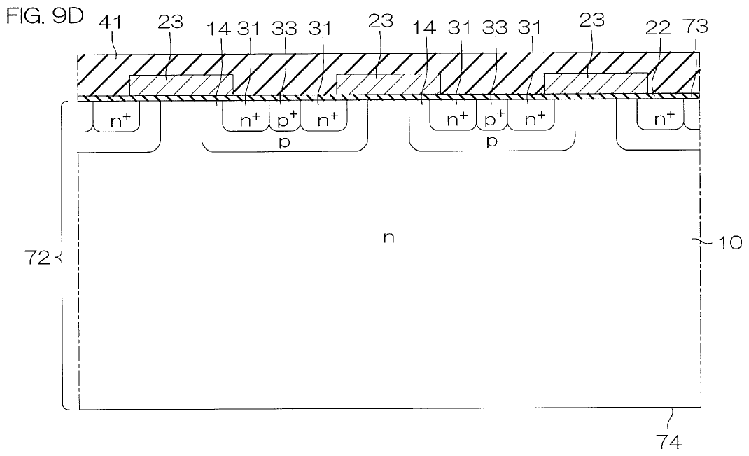

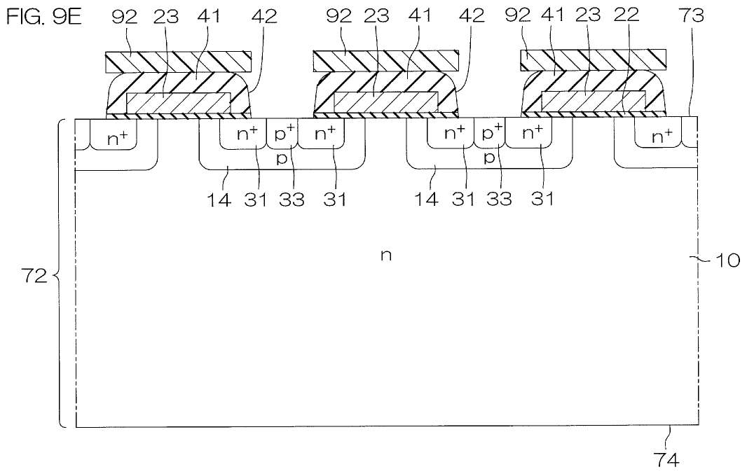

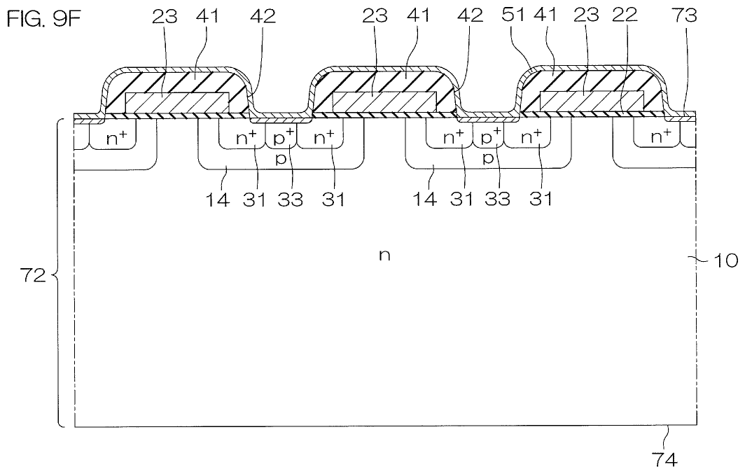

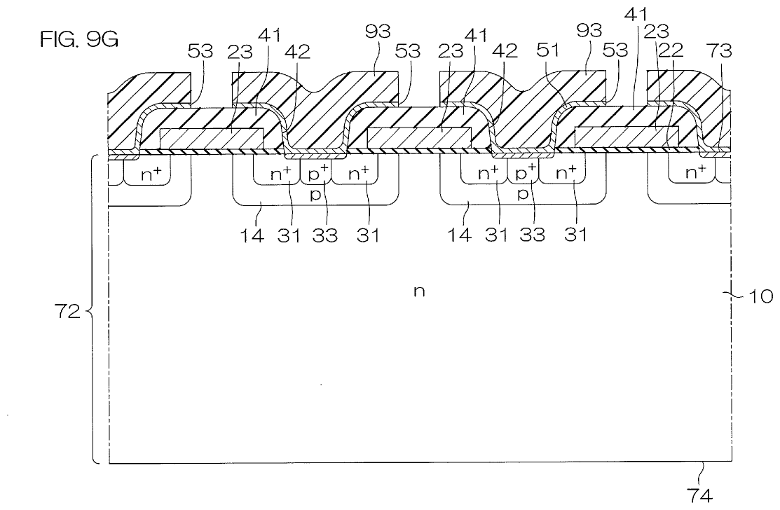

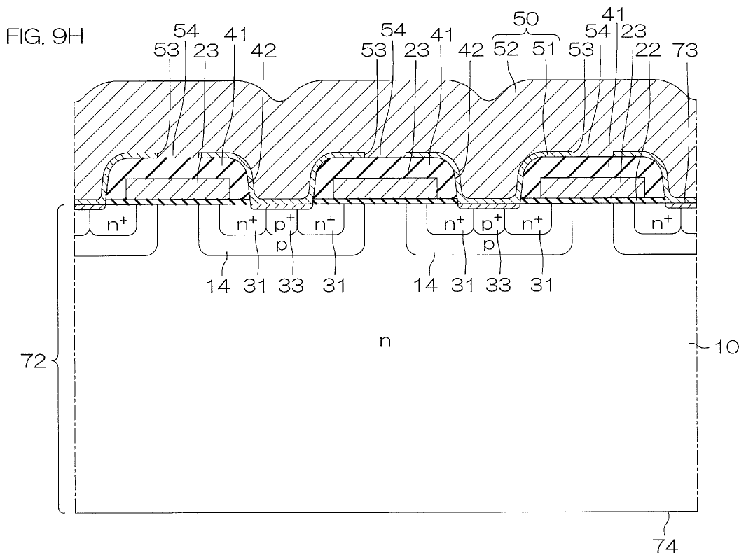

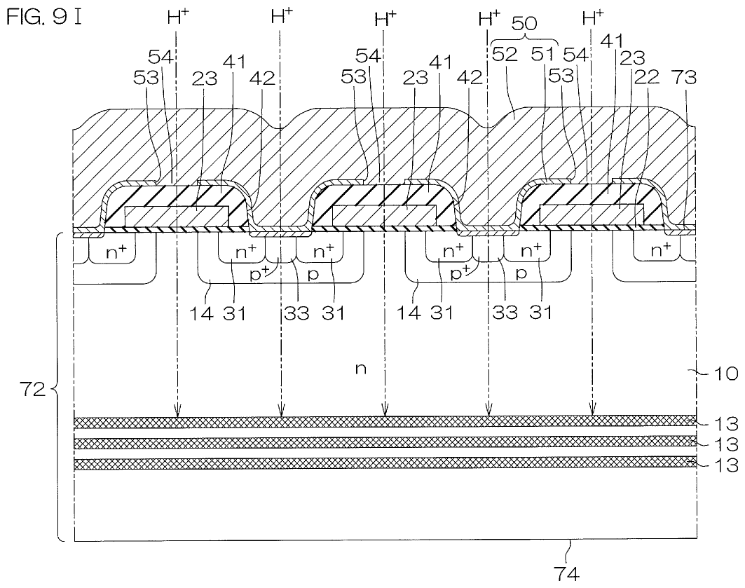

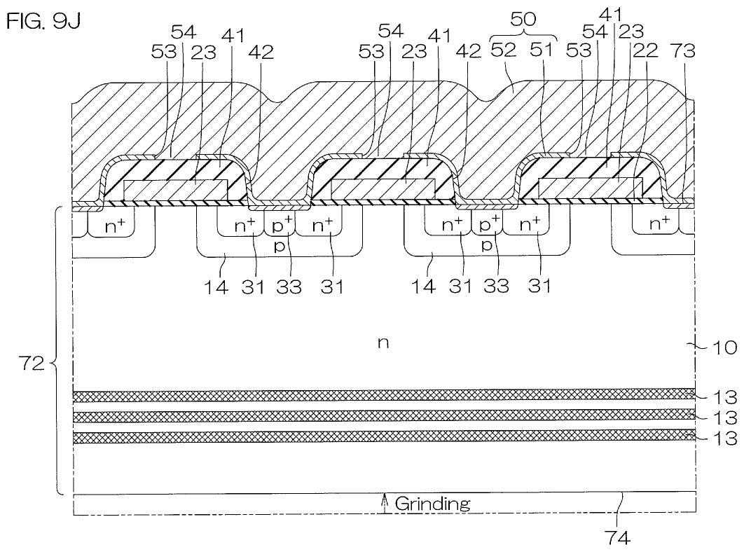

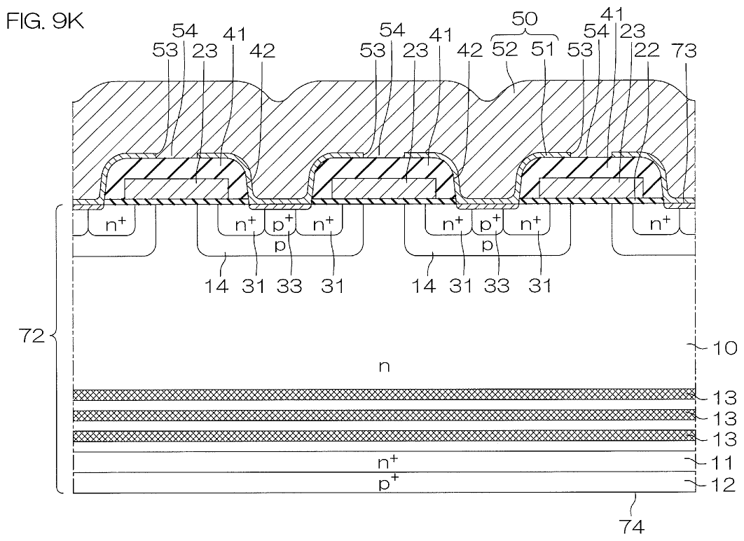

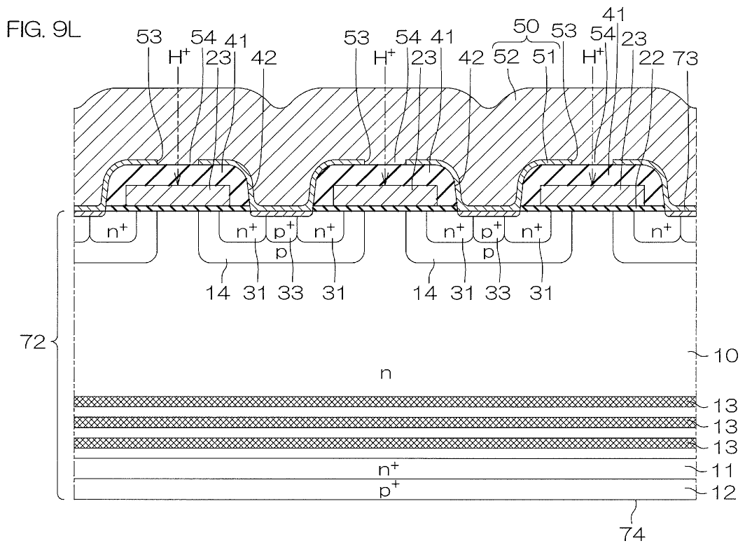

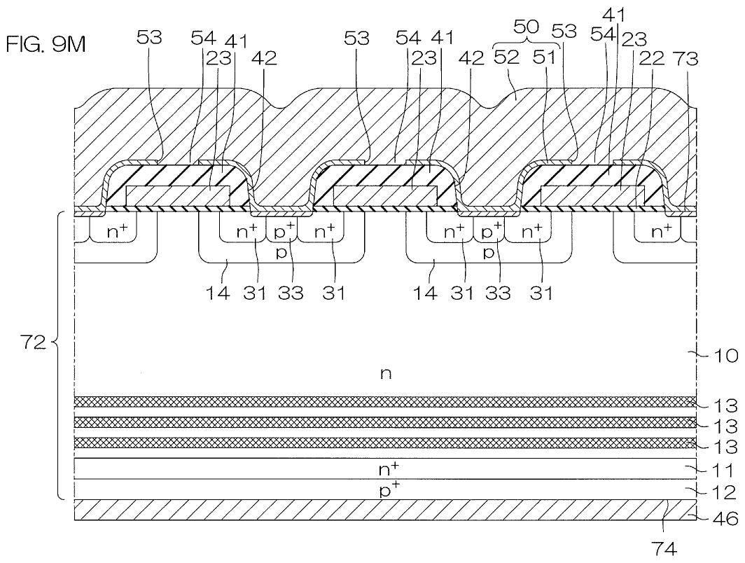

FIGS. 9A to 9M are cross-sectional views for illustrating an example of a manufacturing method for the semiconductor device 81 shown in FIG. 7.

Next, referring to FIG. 9A, the silicon-made wafer 72 is prepared as the base of the semiconductor layer 2. The wafer 72 may have the single-layer structure composed of the FZ wafer that is formed by the FZ method or the CZ wafer that is formed by the CZ method. In any of the FZ and CZ wafer cases, the wafer 72 contains oxygen at a predetermined density. The oxygen density of the wafer 72 may be 1×10¹⁵ cm⁻³ or more and 1×10¹⁹ cm⁻³ or less .

The wafer 72 has the first wafer main surface 73 on one side and the second wafer main surface 74 on the other side. The first wafer main surface 73 and the second wafer main surface 74 correspond to the first main surface 3 and the secondmain surface 4 of the semiconductor layer 2, respectively. Next, the body regions 14, the emitter regions 31, and the contact regions 33 are formed in the surface layer portion of the first wafer main surface 73.

The body regions 14 are formed by selectively introducing p-type impurities into the surface layer portion of the first wafer main surface 73 by an ion implantation method via an ion implantation mask (not shown) . The emitter regions 31 are formed by selectively introducing n-type impurities into the surface layer portion of the body region 14 by an ion implantation method via an ion implantation mask (not shown) . The contact regions 33 are formed by selectively introducing p-type impurities into the surface layer portion of the body region 14 by an ion implantation method via an ion implantation mask (not shown).

Next, referring to FIG. 9B, the gate insulating layer 22 is formed on the first wafer main surface 73. The gate insulating layer 22 is formed as a film along the first wafer main surface 73. The gate insulating layer 22 is formed by a thermal oxidation treatment method or a CVD method. In this embodiment, the gate insulating layer 22 is formed by a thermal oxidation treatment method.

Next, the base electrode layer 77 is formed on the gate insulating layer 22 as the base of the gate electrode 23. The base electrode layer 77 is composed of the electrode material that allows the hydrogen ions to be passed through. In this embodiment, the base electrode layer 77 is composed of the conductive polysilicon layer. The base electrode layer 77 is preferably composed of the n-type polysilicon layer. The base electrode layer 77 may be formed by a CVD method.

Next, referring to FIG. 9C, a resist mask 91 having a predetermined pattern is formed on the base electrode layer 77. The resist mask 91 covers regions in which the plurality of gate electrodes 23 are to be formed in the base electrode layer 77 and exposes the other regions.

Next, unnecessary portions of the base electrode layer 77 are removed via the resist mask 91 by an etching method. The unnecessary portions of the base electrode layer 77 are removed until the gate insulating layer 22 is exposed. The etching method may be a wet etching method and/or a dry etching method. Therefore, the gate electrodes 23 are formed on the gate insulating layer 22. The resist mask 91 is removed thereafter.

Next, referring to FIG. 9D, the intermediate insulating layer 41 is formed on the first wafer main surface 73. The intermediate insulating layer 41 is composed of the hydrogen ion passing insulator. The intermediate insulating layer 41 may have a single-layer structure or a laminated structure including one or both of an SiO₂ layer and an SiN layer. The intermediate insulating layer 41 may have a laminated structure including a plurality of SiO₂ layers. The intermediate insulating layer 41 may include at least one of a USG layer, a PSG layer, and a BPSG layer as an example of the SiO₂ layer. The intermediate insulating layer 41 may be formed by a CVD method.

Next, referring to FIG. 9E, a resist mask 92 having a predetermined pattern is formed on the intermediate insulating layer 41. The resist mask 92 exposes regions in which the plurality of contact openings 42 are to be formed in the intermediate insulating layer 41 and covers the other regions.

Next, unnecessary portions of the intermediate insulating layer 41 and unnecessary portions of the gate insulating layer 22 are removed via the resist mask 92 by an etching method. The etching method may be a wet etching method and/or a dry etching method. Therefore, the plurality of contact openings 42 from which the first wafer main surface 73 is exposed are formed in the intermediate insulating layer 41. In this step, the plurality of contact openings 42 from which the gate electrodes 23 are exposed are formed in the intermediate insulating layer 41, though not shown. The resist mask 92 is removed thereafter.

Next, referring to FIG. 9F, the barrier electrode 51 is formed on the intermediate insulating layer 41. The barrier electrode 51 is formed as a film along the main surface of the intermediate insulating layer 41 and the inner wall of the contact opening 42. The barrier electrode 51 contains the electrode material that allows the hydrogen ions to be absorbed.

In this step, the Ti layer 61 composed of the electrode material that allows the hydrogen ions to be absorbed is first formed. The Ti layer 61 may be formed by an evaporation method and/or a sputtering method. Next, the silicide layer 34 composed of the Ti silicide is formed in a portion in contact with the Ti layer 61 in the first wafer main surface 73 by an RTA (Rapid Thermal Anneal) method. Next, the TiN layer 62 is formed on the Ti layer 61. The TiN layer 62 may be formed by an evaporation method and/or a sputtering method.

One or both of the Ti layer 63 and the W layer 64 may be formed on the TiN layer 62 according to the configuration examples shown in FIGS. 5A to 5D. The Ti layer 63 and the W layer 64 may be formed by an evaporation method and/or a sputtering method.

Next, referring to FIG. 9G, a resist mask 93 having a predetermined pattern is formed on the barrier electrode 51 . The resist mask 93 exposes regions in which the plurality of opening portions 53 are to be formed in the barrier electrode 51 and covers the other regions. The regions in which the plurality of opening portions 53 are to be formed in the barrier electrode 51 are portions covering the intermediate insulating layer 41 or portions covering the semiconductor layer 2 in the barrier electrode 51. In this embodiment, the regions in which the plurality of opening portions 53 are to be formed in the barrier electrode 51 are portions covering the intermediate insulating layer 41 in the barrier electrode 51.

Next, unnecessary portions of the barrier electrode 51 are removed via the resist mask 93 by an etching method. The etching method may be a wet etching method and/or a dry etching method. Therefore, the plurality of opening portions 53 from which portions of the intermediate insulating layer 41 or portions of the semiconductor layer 2 are exposed are formed in the barrier layer 51. In this step, the plurality of opening portions 53 from which portions of the intermediate insulating layer 41 are respectively exposed are formed. The specific form of the opening portions 53 has been mentioned above and will not be described here. The resist mask 93 is removed thereafter.

Next, referring to FIG. 9H, the main electrode 52 is formed on the barrier electrode 51. The main electrode 52 fills the contact openings 42 and the plurality of opening portions 53 and covers the barrier electrode 51. The main electrode 52 is composed of the electrode material that allows the hydrogen ions to be passed through. The main electrode 52 may include at least one of a pure Al layer, an AlSi layer, an AlCu layer, and an AlSiCu layer. The main electrode 52 may be formed by an evaporation method and/or a sputtering method.

Next, unnecessary portions of the barrier electrode 51 and unnecessary portions of the main electrode 52 are removed via a resist mask having a predetermined pattern (not shown) by an etching method. Therefore, the gate main surface electrodes 47 and the emitter main surface electrodes 50 are formed.

Next, referring to FIG. 91, one or a plurality of (plurality in this embodiment) crystal defect regions 13 are formed in regions closer to the second wafer main surface 74 than the first wafer main surface 73. The plurality of crystal defect regions 13 are formed through the same step as mentioned above with respect to FIG. 6Q. The plurality of crystal defect regions 13 serve as at least one of a lifetime killer region, a buffer region, and a field stop region.

Next, referring to FIG. 9J, the wafer 72 is thinned to a desired thickness by grinding the second wafer main surface 74. The second wafer main surface 74 may be ground by a CMP (Chemical Mechanical Polishing) method. The step of grinding the second wafer main surface 74 may be skipped as appropriate.

Next, referring to FIG. 9K, the buffer region 11 is formed in the surface layer portion of the second wafer main surface 74 . The buffer region 11 is formed by introducing n-type impurities into the surface layer portion of the second wafer main surface 74 by an ion implantation method.

The collector region 12 is also formed in the surface layer portion of the second wafer main surface 74 . Specifically, the collector region 12 is formed in the surface layer portion of the second wafer main surface 74 side in the buffer region 11. The collector region 12 is formed by introducing p-type impurities into the surface layer portion of the second wafer main surface 74 by an ion implantation method. The step of forming the buffer region 11 and the step of forming the collector region 12 may be performed in any order. The buffer region 11 may be formed after forming the collector region 12.

Next, referring to FIG. 9L, the hydrogen ions are introduced into the gate insulating layer 22, and the dangling bonds of silicon atoms in the gate insulating layer 22 are hydrogen-terminated by the hydrogen ions. The dangling bonds of silicon atoms in the gate insulating layer 22 are formed due to the step of forming the crystal defect regions 13.

The hydrogen ions are introduced into the gate insulating layer 22 by a hydrogen annealing treatment method. In the hydrogen annealing treatment method, the wafer 72 is annealed in a high-temperature atmosphere containing hydrogen. The hydrogen ions are introduced from the first wafer main surface 73 side into the gate insulating layer 22 . The hydrogen ions introduced into the gate insulating layer 22 are trapped (absorbed) by the barrier electrode 51 and, at the same time, introduced through the opening portions 53 of the barrier electrode 51 into the gate insulating layer 22.

Specifically, the hydrogen ions enter the opening portions 53 of the barrier electrode 51 and pass through the intermediate insulating layer 41 and are introduced into the gate insulating layer 22. More specifically, the hydrogen ions enter the opening portions 53 of the barrier electrode 51 and pass through the main electrode 52, the intermediate insulating layer 41, and the gate electrode 23 and are introduced into the gate insulating layer 22.

Therefore, the dangling bonds of silicon atoms in the gate insulating layer 22 are hydrogen-terminated by the hydrogen ions. In this step, the hydrogen ions are also introduced into the interface region 29 in contact with the gate insulating layer 22 in the first wafer main surface 73.

Therefore, the dangling bonds of silicon atoms in the interface region 29 are hydrogen-terminated by the hydrogen ions.

Next, referring to FIG. 9M, the collector electrode 46 is formed on the second wafer main surface 74 . The collector electrode 46 may include at least one of a Ti layer, an Ni layer, a Pd layer, an Au layer, an Ag layer, and an Al layer. The collector electrode 46 may be formed by an evaporation method and/or a sputtering method.

Subsequently, the wafer 72 is cut selectively such that plurality of semiconductor devices 81 are cut out. The semiconductor devices 81 are thus manufactured through the steps including the foregoing steps.

As described above, the manufacturing method for the semiconductor device 81 includes the steps of forming the gate insulating layer 22 on the wafer 72, forming crystal defect region 13 in the wafer 72 after the step of forming the gate insulating layer 22, and introducing the hydrogen ions into the gate insulating layer 22 after the step of forming the crystal defect region 13. With this manufacturing method, the dangling bonds of silicon atoms in the gate insulating layer 22 can be hydrogen-terminated by the hydrogen ions.

Therefore, the charge traps in the gate insulating layer 22 can be reduced, and the aging degradation of the insulating characteristics can thereby be suppressed. The semiconductor device 81 including the highly reliable gate insulating layer 22 can thereby be manufactured and provided.

The manufacturing method for the semiconductor device 81 includes the step of hydrogen-terminating dangling bonds of silicon atoms in the wafer 72 with the hydrogen ions in the interface region 29 in contact with the gate insulating layer 22 in the wafer 72. Therefore, the aging variation of the insulating characteristics can be appropriately suppressed.

The manufacturing method for the semiconductor device 81 includes the steps of forming the gate electrode 23, forming the intermediate insulating layer 41, forming the barrier electrode 51, and forming the opening portion 53 in the barrier electrode 51, before the step of introducing the hydrogen ions into the gate insulating layer 22.

The gate electrode 23 is formed on the gate insulating layer 22. The intermediate insulating layer 41 covers the gate electrode 23. The barrier electrode 51 contains the electrode material that allows the hydrogen ions to be absorbed and covers the intermediate insulating layer 41. A portion of the intermediate insulating layer 41 or a portion of the semiconductor layer 2 is exposed from the opening portion 53 of the barrier electrode 51. In this manufacturing method, the opening portion 53 of the barrier electrode 51 is formed to expose a portion of the intermediate insulating layer 41.

With the manufacturing method described above, the hydrogen ions introduced into the gate insulating layer 22 are trapped (absorbed) by the barrier electrode 51 and, at the same time, introduced through the opening portion 53 of the barrier electrode 51 into the gate insulating layer 22 . It is therefore possible to suppress absorption of the hydrogen ions by the barrier electrode 51 and appropriately form the Si—H bond in the gate insulating layer 22.

In the step of forming opening portion 53, the opening portion 53 is formed which overlaps at least one (all in this embodiment) of the gate insulating layer 22 and the gate electrode 23 in a plan view. With this manufacturing method, the distance between the gate insulating layer 22 and the opening portion 53 can be shortened. Therefore, the hydrogen ions can be appropriately introduced through the opening portion 53 into the gate insulating layer 22.

In the step of forming opening portion 53, the opening portion 53 is preferably formed to have the width W2 smaller than the width W3 of the gate insulating layer 22. The opening portion 53 is preferably positioned in a region inside the peripheral edge of the gate insulating layer 22 in a plan view. With this manufacturing method, it is possible to expand a margin with respect to a misalignment of the opening portion 53. Therefore, the opening portion 53 can be appropriately formed in a region between mutually adjacent ones of the plurality of contact openings 42 on the intermediate insulating layer 41.

In the step of forming the opening portion 53, the opening portion 53 may be formed to have the width W2 smaller than the width W4 of the gate electrode 23. The opening portion 53 may be positioned in a region inside the peripheral edge of the gate electrode 23 in a plan view. With this manufacturing method, it is possible to reliably expand a margin with respect to a misalignment of the opening portion 53.

In the manufacturing method for the semiconductor device 81, the intermediate insulating layer 41 is preferably formed of the hydrogen ion passing material. Therefore, the hydrogen ions can be introduced efficiently through the intermediate insulating layer 41 into the gate insulating layer 22. The gate electrode 23 is preferably formed of the electrode material that allows the hydrogen ions to be passed through.

Therefore, the hydrogen ions can be introduced efficiently through the gate electrode 23 into the gate insulating layer 22. The main electrode 52 is preferably formed of the electrode material that allows the hydrogen ions to be passed through. Therefore, the hydrogen ions can be introduced efficiently through the main electrode 52 into the gate insulating layer 22.

In the manufacturing method for the semiconductor device 81, an example in which the steps of forming the body regions 14, the emitter regions 33 and the contact regions 33 (see FIG. 9A, etc.) are performed before the step of forming the gate electrode 23 (see FIG. 9B) has been described. However, the steps of forming the body regions 14, the emitter regions 33 and the contact regions 33 (see FIG. 9A, etc.) do not necessarily have to be performed at this timing, and may be performed at any timings before the step of forming the barrier electrode 51 (see FIG. 9E, etc.).

In the manufacturing method for the semiconductor device 81, an example in which the step of forming the crystal defect region 13 (see FIG. 91) is performed after the step of forming the main electrode 52 (see FIG. 9H) and before the step of forming the collector region 12 (buffer region 11) (see FIG. 9K) has been described. However, the step of forming the crystal defect region 13 does not necessarily have to be performed at this timing, and may be performed at any timing after the step of forming the gate insulating layer 22 (see FIG. 9B) and before the step of introducing the hydrogen ions into the gate insulating layer 22 (see FIG. 9L).

In the manufacturing method for the semiconductor device 81, an example in which the step of introducing the hydrogen ions into the gate insulating layer 22 (see FIG. 9L) is performed after the step of forming the collector region 12 (buffer region 11) (see FIG. 9K) has been described. However, the step of introducing the hydrogen ions into the gate insulating layer 22 (see FIG. 9L) does not necessarily have to be performed at this timing, and may be performed at any timing after the step of forming the crystal defect region 13 (see FIG. 9I) and before the step of cutting the wafer 72 (see FIG. 9M) .

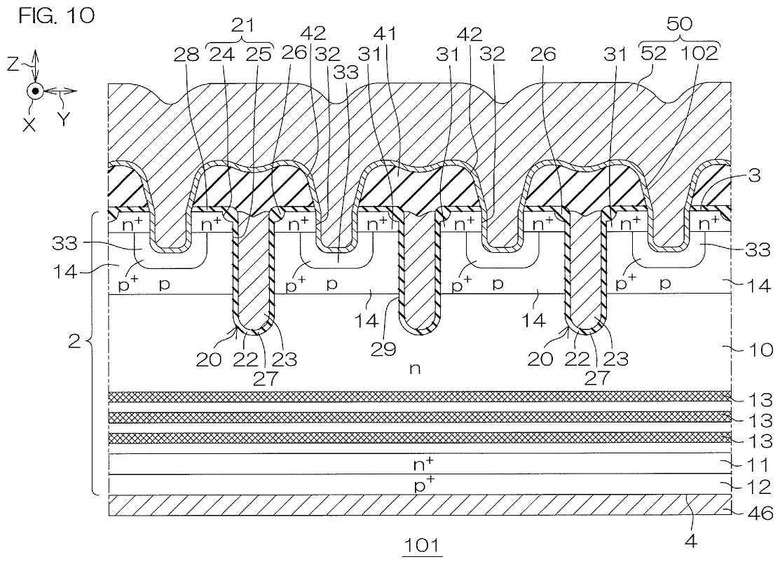

FIG. 10 is a cross-sectional view corresponding to FIG. 3 and showing a semiconductor device 101 according to a third embodiment of the present invention. Structures corresponding to those described for the semiconductor device 1 will hereinafter be designated by the same reference signs to omit description thereof.

Referring to FIG. 10, the emitter main surface electrode 50 (gate main surface electrode 47) according to the semiconductor device 101 includes a barrier electrode 102 composed of the electrode material that allows the hydrogen ions to be passed through instead of the barrier electrode 51 containing the electrode material that allows the hydrogen ions to be absorbed. In this embodiment, the barrier electrode 102 has no opening portion 53.

The barrier electrode 102 preferably includes at least one of a W layer, a WSi layer, a Co layer, an Ni layer, an Mo layer, and a TiN layer. The W layer, the WSi layer, the Co layer, the Ni layer, the Mo layer, and the TiN layer are all composed of the electrode material that allows the hydrogen ions to be passed through.

The barrier electrode 102 may have a single-layer structure composed of any one of a W layer, a WSi layer, a Co layer, an Ni layer, an Mo layer, and a TiN layer. The barrier electrode 102 may have a laminated structure in which at least two layers of a W layer, a WSi layer, a Co layer, an Ni layer, an Mo layer, and a TiN layer are laminated in any order. The TiN layer is preferably formed in combination with at least one of the W layer, the WSi layer, the Co layer, the Ni layer, and the Mo layer. The TiN layer is preferably formed as an uppermost layer of the barrier electrode 102.

The W layer, the WSi layer, the Co layer, the Ni layer, the Mo layer, and the TiN layer are all formed by an evaporation method and/or a sputtering method in the step mentioned above with respect to FIG. 6N. In this case, the silicide layer 34 may or may not be formed on the inner wall of each contact hole.

As described above, the semiconductor device 101 includes the barrier electrode 102 composed of the electrode material that allows the hydrogen ions to be passed through. Therefore, the hydrogen ions can be introduced through the barrier electrode 102 into the gate insulating layer 22 in the step mentioned above with respect to FIG. 6T. It is therefore possible to skip the step of forming the opening portion 53. The semiconductor device 101 including the highly reliable gate insulating layer 22 can thereby be manufactured and provided, and at the same time, man-hours can be reduced.

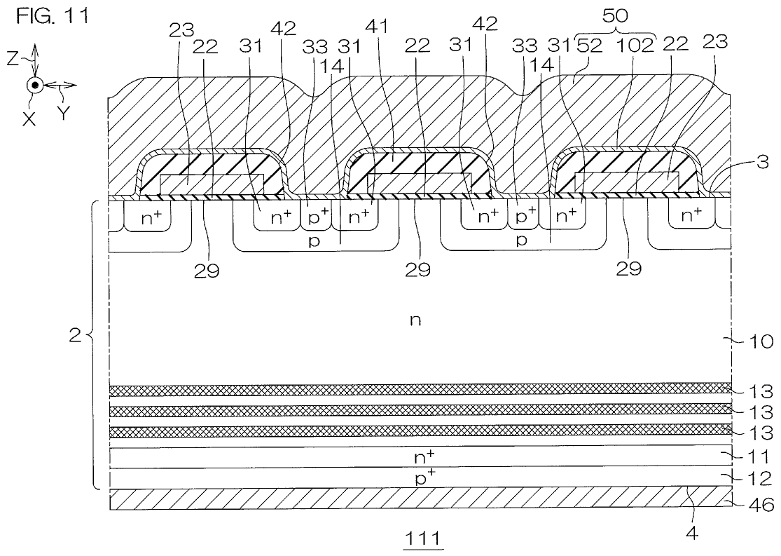

FIG. 11 is a cross-sectional view corresponding to FIG. 8 and showing a semiconductor device 111 according to a fourth embodiment of the present invention. Structures corresponding to those described for the semiconductor device 81 will hereinafter be designated by the same reference signs to omit description thereof.

Referring to FIG. 11, the emitter main surface electrode 50 (gate main surface electrode 47) according to the semiconductor device 111 includes a barrier electrode 102 composed of the electrode material that allows the hydrogen ions to be passed through instead of the barrier electrode 51 containing the electrode material that allows the hydrogen ions to be absorbed. In this embodiment, the barrier electrode 102 has no opening portion 53.

The barrier electrode 102 preferably includes at least one of a W layer, a WSi layer, a Co layer, an Ni layer, an Mo layer, and a TiN layer. The W layer, the WSi layer, the Co layer, the Ni layer, the Mo layer, and the TiN layer are all composed of the electrode material that allows the hydrogen ions to be passed through.

The barrier electrode 102 may have a single-layer structure composed of any one of a W layer, a WSi layer, a Co layer, an Ni layer, an Mo layer, and a TiN layer. The barrier electrode 102 may have a laminated structure in which at least two layers of a W layer, a WSi layer, a Co layer, an Ni layer, an Mo layer, and a TiN layer are laminated in any order. The TiN layer is preferably formed in combination with at least one of the W layer, the WSi layer, the Co layer, the Ni layer, and the Mo layer. The TiN layer is preferably formed as an uppermost layer of the barrier electrode 102.

The W layer, the WSi layer, the Co layer, the Ni layer, the Mo layer, and the TiN layer are all formed by an evaporation method and/or a sputtering method in the step mentioned above with respect to FIG. 9F. In this case, the silicide layer 34 may or may not be formed on the inner wall of each contact hole.

As described above, the semiconductor device 111 includes the barrier electrode 102 composed of the electrode material that allows the hydrogen ions to be passed through. Therefore, the hydrogen ions can be introduced through the barrier electrode 102 into the gate insulating layer 22 in the step mentioned above with respect to FIG. 9L. It is therefore possible to skip the step of forming the opening portion 53. The semiconductor device 111 including the highly reliable gate insulating layer 22 can thereby be manufactured and provided, and at the same time, man-hours can be reduced.

The embodiments of the present invention may be implemented in other forms.

In the above-mentioned first and second embodiments, the barrier electrode 51 having the opening portion 53 that exposes a portion of the semiconductor layer 2 may be formed. It is noted that in this case, a portion of the main electrode 52 comes into contact with the semiconductor layer 2. It should be noted that in this case, the electrode material (e.g. Al) of the main electrode 52 may be diffused into the semiconductor layer 2 to cause the electrical characteristics of the semiconductor layer 2 to fluctuate . To avoid this, the opening portion 53 preferably exposes a portion of the intermediate insulating layer 41 with spacing from the semiconductor layer 2.

In the above-mentioned third and fourth embodiments, alternatively or additionally to the W layer, the WSi layer, the Co layer, the Ni layer, the Mo layer, and the TiN layer, the barrier electrode 102 consisting of a TiW layer or the barrier electrode 102 including a TiW layer may be formed. This can exhibit the same effects as those described in the third and fourth embodiments.

It should be noted that the TiW layer has the property of absorbing the hydrogen ions according to a content amount of the Ti . Therefore, in a case in which the TiW layer is adopted, the barrier electrode 102 is preferably formed with the opening portion 53 according to the property of the TiW layer in the same manner as in the first and second embodiments.

In the above-mentioned first and third embodiments, the trench gate structures 20 may be formed in a grid pattern in a plan view. In the above-mentioned second and fourth embodiments, the planar gate structures 82 may be formed in a grid pattern in a plan view.

In the above-mentioned embodiments, an SiC (silicon carbide)-made semiconductor layer 2 may be adopted instead of the silicon-made semiconductor layer 2. That is, the semiconductor layer 2 may include silicon.

In the above-mentioned embodiments, another structure may be adopted in which the conductivity type of the semiconductor portions is inverted. That is, the p-type portions may be n-type, while the n-type portions may be p-type .

In the above-mentioned embodiments, an n+-type drain region may be formed instead of the p⁺-type collector region 12. The n-type impurity concentration of the drain region may be 1×10¹⁹ cm⁻³ or more and 1×10²¹ cm⁻³ or less. Therefore, a semiconductor device including a MISFET (Metal Insulator Semiconductor Field Effect Transistor) instead of the IGBT can be provided. The semiconductor device including the MISFET instead of the IGBT can also exhibit the same effects as those described in the above-mentioned embodiments.

In the case above, “emitter” and “collector” of the IGBT shall be replaced with “source” and “drain” of the MISFET, respectively, in the description of the above-mentioned embodiments. In this case, the semiconductor layer 2 may has a laminated structure including an n+-type semiconductor substrate that forms a drain region and an n-type epitaxial layer that forms a drift region 10.

Examples of features extracted from the description and the accompanying drawings are set forth below.

[A1] A semiconductor device comprising: a semiconductor layer; a crystal defect region formed in the semiconductor layer; and an insulating layer formed on the semiconductor layer, composed of an insulator containing silicon, and including, in the insulator, an Si—H bond in which a dangling bond of silicon atom is hydrogen-terminated.

[A2] The semiconductor device according to A1, further comprising: an electrode formed on the insulating layer; an intermediate insulating layer covering the electrode; and a barrier electrode covering the intermediate insulating layer, having an opening portion from which at least one of a portion of the intermediate insulating layer and a portion of the semiconductor layer is exposed, and including an electrode material in which a hydrogen ion is absorbed.

[A3] The semiconductor device according to A2, wherein the portion of the intermediate insulating layer is exposed from the opening portion.

[A4] The semiconductor device according to A2 or A3, wherein the opening portion overlaps the insulating layer in a plan view.

[A5] The semiconductor device according to any one of A2 to A4, further comprising: a trench structure having a trench formed in the semiconductor layer, the insulating layer formed on an inner wall of the trench, and the electrode buried in the trench with the insulating layer interposed therebetween; wherein the intermediate insulating layer covers the trench structure.

[A6] The semiconductor device according to A5, wherein the opening portion overlaps the trench structure in a plan view.

[A7] The semiconductor device according to any one of A2 to A4, further comprising: a planar structure including the insulating layer and the electrode; wherein the intermediate insulating layer covers the planar structure.

[A8] The semiconductor device according to A7, wherein the opening portion overlaps the planar structure in a plan view.

[A9] The semiconductor device according to any one of A2 to A8, further comprising: a main electrode filling the opening portion and covering the barrier electrode.

[A10] The semiconductor device according to A1, further comprising: an electrode formed on the insulating layer; an intermediate insulating layer covering the electrode; and a barrier electrode composed of an electrode material which allows a hydrogen ion to pass through and covering the intermediate insulating layer.

[A11] The semiconductor device according to A10, further comprising: a trench structure having a trench formed in the semiconductor layer, the insulating layer formed on an inner wall of the trench, and the electrode buried in the trench with the insulating layer interposed therebetween; wherein the intermediate insulating layer covers the trench structure.

[A12] The semiconductor device according to A10, further comprising: a planar structure including the insulating layer and the electrode; wherein the intermediate insulating layer covers the planar structure.

[A13] The semiconductor device according to any one of A10 to A12, further comprising: a main electrode covering the barrier electrode.

[A14] The semiconductor device according to any one of A1 to A13, wherein the semiconductor layer contains silicon.

[A15] The semiconductor device according to A14, further comprising: an interface region formed in a region of the semiconductor layer that is covered with the insulating layer and having an Si—H bond in which a dangling bond of a silicon atom is hydrogen-terminated.

[A16] The semiconductor device according to any one of A1 to A15, wherein the crystal defect region forms at least one of a lifetime killer region, a buffer region, and a field stop region.

[A17] A manufacturing method for a semiconductor device comprising steps of: preparing a wafer; forming an insulating layer composed of an insulator containing silicon on the wafer; forming a crystal defect region in the wafer by at least one of an ion irradiation method and an electron beam irradiation method after forming the insulating layer; and introducing a hydrogen ion into the insulating layer to hydrogen-terminate a dangling bond of a silicon atom in the insulating layer after forming the crystal defect region.

[A18] The manufacturing method for a semiconductor device according to A17, wherein the step of introducing the hydrogen ion includes a step of introducing the hydrogen ion into the insulating layer by a hydrogen annealing treatment method.

[A19] The manufacturing method for a semiconductor device according to A17 or A18, wherein the step of forming the crystal defect region includes a step of forming a dangling bond of a silicon atom in the insulating layer.

[A20] The manufacturing method for a semiconductor device according to any one of A17 to A19, further comprising steps of: forming an electrode on the insulating layer before the step of introducing the hydrogen ion; forming an intermediate insulating layer covering the electrode before the step of introducing the hydrogen ion; forming a barrier electrode including an electrode material which allows a hydrogen ion to be absorbed and covering the intermediate insulating layer before the step of introducing the hydrogen ion; and removing an unnecessary portion of the barrier electrode to form an opening portion from which at least one of a portion of the intermediate insulating layer and a portion of the wafer is exposed in the barrier electrode before the step of the introducing hydrogen ions; wherein the hydrogen ion is introduced through the opening portion of the barrier electrode into the insulating layer during the step of the introducing hydrogen ions.

[A21] The manufacturing method for a semiconductor device according to any one of A17 to A19, further comprising steps of : forming an electrode on the insulating layer before the step of introducing the hydrogen ions; forming an intermediate insulating layer covering the electrode before the step of introducing the hydrogen ion; and forming a barrier electrode including an electrode material which allows a hydrogen ion to pass through and covering the intermediate insulating layer before the step of introducing the hydrogen ion; wherein the hydrogen ion is introduced through the barrier electrode into the insulating layer during the step of introducing the hydrogen ion.

This application corresponds to Japanese Patent Application No. 2019-153947 filed on Aug. 26, 2019 with the Japan Patent Office, the disclosure of which is incorporated herein by reference in its entirety. While embodiments of the present invention have heretofore been described in detail, these are merely specific examples used to clarify the technical content of the present invention, and the present invention should not be interpreted as being limited only to these specific examples. The scope of the present invention shall be limited only by the appended Claims.

### REFERENCE SIGNS LIST

1: Semiconductor device
2: Semiconductor layer
13: Crystal defect region
20: Trench gate structure (trench structure)
21: Gate trench (trench)
22: Gate insulating layer (insulating layer)
23: Gate electrode (electrode)
29: Interface region
41: Intermediate insulating layer
51: Barrier electrode
52: Main electrode
53: Opening portion
72: Wafer
81: Semiconductor device
82: Planar gate structure (planar structure)
101: Semiconductor device
102: Barrier electrode
111: Semiconductor device

1. A semiconductor device comprising:
a semiconductor layer;
a crystal defect region formed in the semiconductor layer; and
an insulating layer formed on the semiconductor layer, composed of an insulator containing silicon, and including, in the insulator, an Si—H bond in which a dangling bond of silicon atom is hydrogen-terminated.

2. The semiconductor device according to claim 1, further comprising:
an electrode formed on the insulating layer;
an intermediate insulating layer covering the electrode; and
a barrier electrode covering the intermediate insulating layer, having an opening portion from which at least one of a portion of the intermediate insulating layer and a portion of the semiconductor layer is exposed, and including an electrode material in which a hydrogen ion is absorbed.

3. The semiconductor device according to claim 2,
wherein the portion of the intermediate insulating layer is exposed from the opening portion.

4. The semiconductor device according to claim 2,
wherein the opening portion overlaps the insulating layer in a plan view.

5. The semiconductor device according to claim 2, further comprising:
a trench structure having a trench formed in the semiconductor layer, the insulating layer formed on an inner wall of the trench, and the electrode buried in the trench with the insulating layer interposed therebetween;
wherein the intermediate insulating layer covers the trench structure.

6. The semiconductor device according to claim 5, wherein the opening portion overlaps the trench structure in a plan view.

7. The semiconductor device according to claim 2, further comprising:
a planar structure including the insulating layer and the electrode;
wherein the intermediate insulating layer covers the planar structure.

8. The semiconductor device according to claim 7,
wherein the opening portion overlaps the planar structure in a plan view.

9. The semiconductor device according to claim 2, further comprising:
a main electrode filling the opening portion and covering the barrier electrode.

10. The semiconductor device according to claim 1, further comprising:
an electrode formed on the insulating layer;
an intermediate insulating layer covering the electrode; and
a barrier electrode composed of an electrode material which allows a hydrogen ion to pass through and covering the intermediate insulating layer.

11. The semiconductor device according to claim 10, further comprising:
a trench structure having a trench formed in the semiconductor layer, the insulating layer formed on an inner wall of the trench, and the electrode buried in the trench with the insulating layer interposed therebetween;
wherein the intermediate insulating layer covers the trench structure.

12. The semiconductor device according to claim 10, further comprising:
a planar structure including the insulating layer and the electrode;
wherein the intermediate insulating layer covers the planar structure.

13. The semiconductor device according to claim 10, further comprising:
a main electrode covering the barrier electrode.

14. The semiconductor device according to claim 1,
wherein the semiconductor layer contains silicon.

15. The semiconductor device according to claim 14, further comprising:
an interface region formed in a region of the semiconductor layer that is covered with the insulating layer and having an Si—H bond in which a dangling bond of a silicon atom is hydrogen-terminated.

16. A manufacturing method for a semiconductor device comprising steps of:
preparing a wafer;
forming an insulating layer composed of an insulator containing silicon on the wafer;
forming a crystal defect region in the wafer by at least one of an ion irradiation method and an electron beam irradiation method after forming the insulating layer; and
introducing a hydrogen ion into the insulating layer to hydrogen-terminate a dangling bond of a silicon atom in the insulating layer after forming the crystal defect region.

17. The manufacturing method for the semiconductor device according to claim 16,
wherein the step of introducing the hydrogen ion includes a step of introducing the hydrogen ion into the insulating layer by a hydrogen annealing treatment method.

18. The manufacturing method for the semiconductor device according to claim 16,
wherein the step of forming the crystal defect region includes a step of forming a dangling bond of a silicon atom in the insulating layer.

19. The manufacturing method for the semiconductor device according to claim 16, further comprising steps of:
forming an electrode on the insulating layer before the step of introducing the hydrogen ion;
forming an intermediate insulating layer covering the electrode before the step of introducing the hydrogen ion;
forming a barrier electrode including an electrode material which allows a hydrogen ion to be absorbed and covering the intermediate insulating layer before the step of introducing the hydrogen ion; and
removing an unnecessary portion of the barrier electrode to form an opening portion from which at least one of a portion of the intermediate insulating layer and a portion of the wafer is exposed in the barrier electrode before the step of the introducing hydrogen ions;
wherein the hydrogen ion is introduced through the opening portion of the barrier electrode into the insulating layer during the step of the introducing hydrogen ions.

20. The manufacturing method for the semiconductor device according to claim 16, further comprising steps of:
forming an electrode on the insulating layer before the step of introducing the hydrogen ions;
forming an intermediate insulating layer covering the electrode before the step of introducing the hydrogen ion; and
forming a barrier electrode including an electrode material which allows a hydrogen ion to pass through and covering the intermediate insulating layer before the step of introducing the hydrogen ion;
wherein the hydrogen ion is introduced through the barrier electrode into the insulating layer during the step of introducing the hydrogen ion.
